(19) United States
(12) Patent Application Publication
(10) Pub. No.: US 2026/0312361 A1
(43) Pub. Date: Oct. 8, 2026

(54) INTEGRATED FREQUENCY COMB GENERATORS WITH COMPENSATED OPTICAL CAVITY STRUCTURES

(71) Applicant: Mellanox Technologies, Ltd., Yokneam (IL)

(72) Inventors: Roy RUDNICK, Tel Aviv (IL); Isabelle CESTIER, Haifa (IL); Uziel KOREN, Haifa (IL); Elad MENTOVICH, Tel Aviv (IL)

(21) Appl. No.: 19/540,797

(22) Filed: Feb. 16, 2026

Related U.S. Application Data
(63) Continuation-in-part of application No. 19/171,991, filed on Apr. 7, 2025.

(51) Int. Cl. H01S 5/026; H01S 3/10; H01S 3/1115; H01S 5/125

(52) U.S. Cl. CPC H01S 5/026; H01S 3/10046; H01S 3/1115; H01S 5/125

(57) ABSTRACT

According to certain embodiments, a colliding pulse mode-locked (CPM) laser is provided. The CPM laser includes an optical cavity including at least two gain sections. A saturable absorber is disposed between adjacent gain sections of the at least two gain sections. A first gain section of the at least two gain sections and a second gain section of the at least two gain sections have respective effective lengths that are equal. Methods for fabricating a CPM laser are also provided.

### CROSS-REFERENCE TO RELATED APPLICATION(S)

This application is a continuation-in-part of U.S. application Ser. No. 19/171,991, filed Apr. 7, 2025, the content of which is incorporated herein by reference in its entirety.

### BACKGROUND

As artificial intelligence and/or machine learning use increases, the amount of information being communicated between large clusters of computing resources (e.g., graphical processing units (GPUs), central processing units (CPUs), data processing units (DPUs), and/or the like) is also increasing. Wavelength division multiplexing (WDM) may be used to increase the density of interfaces between clusters of computing resources. WDM is conventionally accomplished using multiple distributed feedback (DFB) lasers. However, such implementations of WDM tend to have relatively large footprints and require substantial power consumption. Accordingly, a need exists for power efficient and size efficient optical sources for use in WDM applications.

### GENERAL DESCRIPTION

Datacenters rely on a fast and robust communication infrastructure. This is achieved by using optical interconnects, especially between different server racks. Each physical link employing a single optical fiber may include multiple communication channels, which are distinguished by different wavelengths in wavelength division multiplexing (WDM) systems. Such optical interconnects tend to include transceivers that are in optical communication with one another via one or more optical fibers. A transceiver includes one or more optical signal generating components and/or one or more optical signal detecting components. For example, a transceiver may include one or more semiconductor devices (e.g., vertical cavity surface emitting lasers (VCSELs); distributed-feedback (DFB) lasers; light emitting diodes (LEDs); modulators such as electro-absorption modulators, intensity and/or phase modulators, and other modulators; electro-absorption modulated lasers (EML); and/or the like) configured to generate optical signals and/or one or more semiconductor devices (e.g., photodiodes) configured for detecting optical signals.

The transmitters in optical WDM transceiver modules are typically based on arrays of discrete single wavelength lasers, such as the distributed feedback (DFB) lasers. However, in order to decrease power consumption and complexity, these lasers could be replaced by a single comb laser. The comb laser generates a range of discrete, equally spaced frequencies.

As transceivers increase their line bitrate, currently from 25 Gbit/s to 50 Gbit/s and then to 100 Gbit/s, as well as upgrade the modulation order from present techniques like non-return-to-zero (NRZ) to pulse amplitude modulation level 4 (PAM-4), the challenge is how to scale the power consumption by the laser sources because these increments require an increase in the signal-to-noise ratio (SNR) of the transmitter.

For example, when moving from NRZ to PAM-4 at the same bitrate, the SNR is reduced by a factor of 3. Therefore, the power needs to increase by a factor of 3 just to maintain the same bit error rate (BER) count as before.

When moving from a PAM-4 to PAM-8 (PAM level 8), both operating at the same bitrate, the SNR needs to be increased to ensure the PAM-8 signal reach the same BER as in the case of PAM-4.

Supporting a sustainable relation between SNR and BER typically requires increasing the available power provided by the laser source, which increases cost. As a result, lasers need to generate more light, which in turn, increases the power consumption above a linear scaling and introduces heat dissipation strain and thermal management challenges, at the same time.

This is particularly relevant for transceivers that need to be encapsulated in standardized pluggable forms, which have limited heat dissipation properties and small space, such that they rely on air flow design, thereby limiting the amount of power transceivers can take from the main rack by the form-factor standards.

Frequency comb generators seek to replace arrays of discrete laser sources with one single laser source. The light from the laser is subsequently split into several different light beams at different wavelengths, and each of these beams is used to convey an individual data stream.

Traditional frequency comb generators have been constructed using discrete components for applications that allow for a large footprint, such as in the fields of metrology and sensing. Such devices, however, are bulky and do not meet requirements for the integrated photonics challenge.

Various embodiments provide frequency comb generators with active optical cavities. In various embodiments, the frequency comb generators are monolithic and/or on-chip frequency comb lasers. This enables a frequency comb generator to be directly integrated with a photonic integrated circuit, for example. The laser pulses generated by the frequency comb generator comprise discrete and regularly spaced spectral lines or “teeth” generating a large number of spectral lines having a configurable line spacing. These spectral lines or teeth may be used to perform dense WDM, in some embodiments. The frequency comb generators is capable of making an affordable, efficient, high power with desirable mode spacing frequency comb source. Dense low-power interfaces are paramount to continue scaling AI/ML systems to interconnect large clusters (GPUs, CPUs, DPUs, . . .). Compared to multiple DFB lasers implementation a monolithic frequency comb laser has a smaller footprint and lower power consumption.

In certain applications, a frequency comb generator may be coupled to an output waveguide (e.g., directly, evanescently, and/or the like). The output waveguide may be used to optically couple the frequency comb generator to one or more modulators, multiplexers, a photonic integrated circuit (PIC), and/or the like. For example, the frequency comb generator may be part of an interconnect used for optical communications.

One example type of frequency comb laser is a colliding pulse mode-locking (CPM) laser. A CPM laser generally includes an active optical cavity that has a gain material disposed therein. The gain material is divided into segments or sections that are generally separated from one another by saturable absorbers.

In a CPM laser, two or more counter-propagating pulses collide at a specific location within the cavity, usually at a saturable absorber or other segment/section separation component. These interactions can enhance pulse shortening and stability due to pulses reinforcing each other's peak intensity at the collision point. When the CPM laser is harmonically mode-locked, multiple pulse pairs collide within a single round trip, effectively increasing the frequency of pulse collisions and thereby increasing the repetition rate. Multiple pulses are generated in the cavity such that they are spaced evenly along the round-trip path. For example, at the second harmonic, two pairs of counter-propagating pulses collide per round trip, doubling the effective repetition rate. However, it is imperative that the propagating pulses in the cavity meet at the saturable absorber sections. Traditional cleaving does not provide sufficient precision in the matching of the effective lengths of the optical cavity segments and/or sections to ensure efficient harmonic generation.

Various embodiments provide multiple options for fabricating a CPM laser having precisely matched optical cavity segments and/or sections. These options include micro-cleaving by forming a cantilever by etching below the waveguide at a desired crystal plane and the using ultrasonic vibration to micro-cleave at the desired crystal plane. This will result in high quality mirrors at the laser facets on both sides. Another option is to use lithographic etching (e.g., by etching mirror facets) to set the length of the segments and/or sections at high accuracy. In another option, a phase change section is added to one or both ends of one or more segments or sections. This may be implemented by adding an additional electrode to control a portion of one of the gain sections current to induce a phase change by changing the carrier densities effectively changing the effective length to align it with the other side of the cavity length. The phase change section(s) may then be used to dynamically adjust the effective length of the corresponding optical cavity segment(s) and/or section(s) by applying a current thereto. Applying high current to a specific section creates gain saturation, preventing additional gain and changing the phase and effective index.

In another example, a C-shaped optical cavity is formed with the collision point/saturable absorber place at the center point of the C. The arms of the C are cleaved in the same process such that the arms are cleaved along the same crystal plane increasing the cleaving accuracy. In another option, the effective length of each section of the cavity is defined by a grating defined and/or formed using a lithographic process, for example. The resulting CPM laser is an affordable, efficient, high power frequency comb source that provides spectral lines with desirable mode spacing. In particular, such CPM lasers are configured for providing a section accuracy length to ensure that co propagating pulses meet in the designated saturable absorber for harmonic generation, resulting in a stable and reliable frequency comb generation.

Various embodiments provide optical interconnects that each include CPM lasers of various embodiments. The optical interconnects may be configured to connect between chips or between different communication systems. For example, it might provide optical interconnecting for network interface controller (NIC) to switch, switch to switch, and/or chip to chip. Optical interconnects can be used in a variety of applications, such as switches, processing units (e.g., graphics processing units (GPUs), etc.). An optical interconnect can include an optical link (e.g., optical fiber) to transmit an optical signal. Optical interconnect bandwidth can be scaled by transmitting an optical signal including multiple wavelengths using the same optical link. In doing so, the transmitter is tuned to generate the optical signal including multiple carrier wavelengths (e.g., possibly via the CPM laser or an array of CPM lasers). Moreover, each modulator of a modular array can be tuned to receive and modulate a respective carrier frequency. Ordering the multiple wavelengths can be important to ensure that the transmitter and receiver are properly communicating data contained within the optical signal.

In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

The optical interconnect may include a substrate and an electro-optical component (CPM laser, photodiode, etc.) supported by the substrate and configured to convert electrical signals to optical signals or vice versa. The optical interconnect may further include a transmission block defining a receiving surface configured to receive an optical fiber, and a waveguide configured to transmit optical signals between the electro-optical component and the receiving surface such that in an operational configuration in which the receiving surface receives an optical fiber, the electro-optical component and the optical fiber are in optical communication.

While the present disclosure illustrates and describes the optical interconnect without a housing or other protective casing, as would be understood by one of ordinary skill in the art in light of the present disclosure, some or all of the optical interconnect may be supported or enclosed by any housing used in communications systems to protect the components supported therein (e.g., as part of Quad Small Form-factor Pluggable (QSFP) connectors, Small Form Pluggable (SFP) connectors, or the like). Furthermore, the substrate hosting the electro-optical component may be substantially rectangular shape and/or may be dimensioned (e.g., sized and shaped) for use in any communication system regardless of geometric constraints (e.g., L-shaped, squared-shaped, etc.).

In various embodiments, an optical interconnect for receiving an optical fiber may be implemented in a flip-chip configuration. In certain embodiments, the optical interconnect is configured as a flip-chip component such that a longitudinal axis of the first adiabatic transition profile of the optical interconnect and a longitudinal axis of the second adiabatic transition profile of the optical interconnect may be collinear. Said differently, the orientation of the optical interconnect in such an embodiment does not require a mirror or other reflective surface to redirect optical signals between the electro-optical component and the receiving surface. As would be evident to one of ordinary skill in the art in light of the present disclosure, however, the optical interconnect in a flip-chip configuration may also include one or more mirrors (e.g., reflective surfaces) to accommodate optical fibers received at varying angles. In some optical interconnect embodiments, only mirrors may be operationally configured to redirect light given that at some bending radii, light may remain confined to the waveguide. Accordingly, embodiments of a field replaceable modular optical interconnect unit are described that are configured to be received by a main switch system box. The field replaceable modular optical interconnect unit comprises a housing comprising at least a front panel, a rear panel, and side panels extending between the front and rear panels, a printed circuit board assembly supported within the housing, an optical module supported on the printed circuit board assembly and configured to convert between optical signals and corresponding electrical signals for respectively transmitting or receiving optical signals through a fiber optic cable, a board-to-board connector disposed on the rear panel of the housing and configured to enable electrical signals to be transmitted between the printed circuit board assembly and a main switch system box, and an external connector disposed on the front panel of the housing and configured to engage an external optical fiber for transmitting optical signals between the optical module and an external component. The field replaceable modular optical interconnect unit may be configured to be electrically connected to the main switch system box via engagement of the board-to-board connector with a corresponding connector of the main switch system box when the housing is received by the main switch system box.

In some embodiments, the optical module may be a mid-board optical module (MBOM), and/or the field replaceable modular optical interconnect unit may comprise a plurality of external connectors. For example, the external connector may be a first external connector, and the field replaceable modular optical interconnect unit may further comprise a second external connector disposed on the front panel of the housing and configured to enable transmission of electrical signals between the printed circuit board assembly and an external component connected thereto.

In a typical optical interconnect Vertical Cavity Surface Emitting Laser (VCSEL) diodes are utilized as light emitters to transmit binary or digital data over optical fibers. However, the light source may in principle be any suitable light source and the transmitted waveform may be any suitable waveform for transmitting information. Most light emitters have a threshold current above which they substantially begin to emit light. Increasing the current driven through the emitter from zero to above said threshold may be time consuming, and therefore a bias current is typically driven through the light source. The bias current can be set just below, at the threshold, or above the threshold, but it also is often set to be well above threshold. This bias current is often programmable so as the same circuit design may be utilized to drive different light emitters and/or be used for different applications. Additional time varying current which modulates the emission from the light emitter is referred to as the modulation current.

In some embodiments, the disclosed technique provides an electro-optical (EO) interconnect assembly comprising a pair of pluggable EO transceivers connected at respective ends of an optical fiber. The EO transceivers are typically used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

The present disclosure describes CPM lasers comprising an optical cavity having segments or sections with substantially equal effective length. In certain embodiments, the effective length of the segments or sections of the optical cavity are within 1% of one another. In some embodiments, the effective length of the segments or sections of the optical cavity are within 0.01% of one another. In some embodiments, the CPM lasers may be incorporated into optical interconnects (e.g., as optical signal generating components, optical signal detecting components, and/or the like).

According to one aspect, a method for fabricating a colliding pulse mode-locking (CPM) laser is provided. In an example embodiment, the method includes etching at least a portion of a first gain section to define an effective length of the first gain section, wherein the first gain section is one of at least two gain sections of a cavity of the CPM laser.

In an example embodiment, the first gain section is separated from a second gain section of the at least two gain sections by a saturable absorber and the effective length of the first gain section is defined to be substantially equal to an effective length of the second gain section. In various embodiments, the effective length of a gain section is less than the working distance of the optics coupling the light.

In an example embodiment, the etching is performed across an entire end of the first gain section.

In an example embodiment, the etching is performed to define a cantilevered portion at an end of the first gain section and the method further comprises applying ultrasonic vibrations to cause an unetched portion of the end of the first gain section to cleave at a crystal face corresponding to the end of the first gain section.

In an example embodiment, the CPM laser comprises a ridge waveguide comprising the first gain section and a waveguide structure and the crystal face is cleaved to define a reflective end of the waveguide structure.

According to another aspect, a method for fabricating a CPM laser. In an example embodiment, the method includes forming a saturated gain phase change section at a first end of a first gain section, wherein the first gain section is one of at least two gain sections of a cavity of the CPM laser.

In an example embodiment, the saturated gain phase change section is configured to dynamically tune an effective length of the first gain section.

In an example embodiment, the method further includes forming a saturable absorber, wherein the saturable absorber separates the first gain section from a second gain section of the at least two gain sections.

According to another aspect, a method for fabricating a CPM laser is provided. In an example embodiment, the method includes forming a C-shaped optical cavity comprising a first gain section and a second gain section that are separated from one another by a saturable absorber located at a center of a curve of the C-shaped optical cavity; and cleaving both the first gain section and the second gain section in a same cleaving process.

In an example embodiment, the method further includes, prior to cleaving the first gain section and the second gain section, etching partially through respective ends of the first gain section and the second gain section to define respective cantilevered portions at the respective ends of the first gain section and the second gain section and the cleaving is configured to cleave off the respective cantilevered portions.

In an example embodiment, the first gain section and the second gain section have the same effective length.

According to another aspect, a method for fabricating a CPM laser is provided. In an example embodiment, the method includes forming a first grating in a first gain section of an optical cavity comprising at least two gain sections, the first grating defining an effective length of the first gain section and configured to substantially reflect light characterized by wavelengths within a selected wavelength range.

In an example embodiment, the first grating is formed using at least one lithographic process.

In an example embodiment, the method further includes forming a second grating in a second gain section of the optical cavity, the second grating defining an effective length of the second gain section and configured to substantially reflect light characterized by wavelengths within the selected wavelength range.

In an example embodiment, the first grating comprises alternating layers of a first material having a first mode effective refractive index and a second material having a second mode effective refractive index, the first mode effective refractive index is not equal to the second mode effective refractive index, and a difference between the first mode effective refractive index and the second mode effective refractive index defines a width of the selected wavelength range.

According to another aspect, a CPM laser is provided. In an example embodiment, the CPM laser includes an optical cavity comprising at least two gain sections, wherein a saturable absorber is disposed between adjacent gain sections of the at least two gain sections and wherein a first gain section of the at least two gain sections and a second gain section of the at least two gain sections have respective effective lengths that are equal, meaning the effective optical lengths are equal.

In an example embodiment, the optical cavity is C-shaped and the saturable absorber is disposed at a center of a curve of the C-shaped optical cavity.

In an example embodiment, at least one gain section of the at least two gain sections comprises a grating configured to define an effective length of the at least one gain section and configured to substantially reflect light characterized by wavelengths within a selected wavelength range.

In an example embodiment, at least one gain section of the at least two gain sections is defined at least in part by a saturated gain phase change section.

In an example embodiment, at least one gain section of the at least two gain sections is defined at least in part by a micro-cleaved or etched end.

According to another aspect, a method is provided. The method comprises fabricating a colliding pulse mode-locked (CPM) laser having a first gain section and a second gain section. The first gain section and the second gain section have respective effective lengths that are substantially equal such that co-propagating pulses generated within the first gain section and the section gain section, respectively, collide at a boundary between the first gain section and the second gain section to cause harmonic generation.

In an example embodiment, fabricating the CPM laser comprises etching at least a portion of the first gain section to define an effective length of the first gain section, wherein the first gain section is one of at least two gain sections of a cavity of the CPM laser.

In an example embodiment, the boundary between the first gain section and the second gain section is a saturable absorber and the effective length of the first gain section is defined to be substantially equal to an effective length of the second gain section.

In an example embodiment, the CPM laser further comprises a third gain section with the second gain section positioned between the first gain section and the third gain section and an effective length of at least one of the first gain section or the third gain section is determined based at least in part on a cleaving distance of a cleaving process to be used to define an end of the at least one of the first gain section or the third gain section.

In an example embodiment, the second gain section has a middle section effective length and a side gain section effective length of the at least one of the first gain section or the third gain section is determined based on the middle section effective length and an effective length corresponding to the cleaving distance.

In an example embodiment, fabricating the CPM laser comprises performing the cleaving process to define the end of the at least one of the first gain section or the third gain section.

In an example embodiment, the method further includes forming a saturable absorber, wherein forming the saturable absorber comprises electrically isolating the saturable absorber from the first gain section and the second gain section and defining electrodes configured for injecting current into the saturable absorber, wherein the saturable absorber is the boundary that separates the first gain section from the second gain section.

In an example embodiment, fabricating the CPM laser comprises forming a C-shaped optical cavity comprising the first gain section and the second gain section and the boundary between the first gain section and the second gain section is a saturable absorber located at a center of a curve of the C-shaped optical cavity; and cleaving both the first gain section and the second gain section in a same cleaving process.

In an example embodiment, the method further includes, prior to cleaving the first gain section and the second gain section, etching partially through respective ends of the first gain section and the second gain section to define respective cantilevered portions at the ends of the first gain section and the second gain section and the cleaving is configured to cleave off the cantilevered portions.

In an example embodiment, the first gain section and the second gain section have the same effective length.

In an example embodiment, fabricating the CPM) laser further includes forming a first grating in the first gain section of an optical cavity comprising the first gain section and the second gain section, the first grating defining an effective length of the first gain section and configured to substantially reflect light characterized by wavelengths within a selected wavelength range.

In an example embodiment, the first grating is formed using at least one lithographic process.

In an example embodiment, the method further includes forming a second grating in the second gain section of the optical cavity, the second grating defining an effective length of the second gain section and configured to substantially reflect light characterized by wavelengths within the selected wavelength range.

In an example embodiment, the first grating comprises alternating layers of a first material having a first mode effective refractive index and a second material having a second mode effective refractive index, the first mode effective refractive index is not equal to the second mode effective refractive index, and a difference between the first mode effective refractive index and the second mode effective refractive index defines a width of the selected wavelength range.

According to another aspect, a colliding pulse mode-locked (CPM) laser is provided. In an example embodiment, the CPM laser includes an optical cavity comprising at least two gain sections, wherein a saturable absorber is disposed between adjacent gain sections of the at least two gain sections and wherein a first gain section of the at least two gain sections and a second gain section of the at least two gain sections have respective effective lengths that are substantially equal.

In an example embodiment, the optical cavity is a C-shaped optical cavity and the saturable absorber is disposed at a center of a curve of the C-shaped optical cavity.

In an example embodiment, at least one gain section of the at least two gain sections is defined at least in part by cleaved end.

In an example embodiment, an effective length of the gain section that is defined at least in part a cleaved end is configured such that an effective length of the gain section that is defined at least in part by the cleaved end corresponds to a cleaving distance of a cleaving process used to form the cleaved end.

In an example embodiment, the active material of the at least two gain sections comprises at least one layer of Quantum Dots (QD) or Quantum Dashes (QDash).

In an example embodiment, the CPM laser is configured to operate with a repetition rate of at least 100 GHz.

According to another aspect, an optical transceiver is provided. In an example embodiment, the optical transceiver includes a CPM laser. The CPM laser includes an optical cavity comprising at least two gain sections, wherein a saturable absorber is disposed between adjacent gain sections of the at least two gain sections and wherein a first gain section of the at least two gain sections and a second gain section of the at least two gain sections have respective effective lengths that are equal.

For example, optical transceivers are provided that include various embodiments of CPM lasers disclosed herein as optical sources.

According to another aspect, an optical interconnect is provided. The optical interconnect includes a first transceiver, a second transceiver, and an optical fiber placing the first transceiver in optical communication with the second transceiver. At least one of the first transceiver or the second transceiver includes a CPM laser. The CPM laser includes an optical cavity comprising at least two gain sections, wherein a saturable absorber is disposed between adjacent gain sections of the at least two gain sections and wherein a first gain section of the at least two gain sections and a second gain section of the at least two gain sections have respective effective lengths that are equal.

According to another aspect, a datacenter network is provided. The datacenter network includes a plurality of optical interconnects configured to provide optical communication channels between respective computing elements (e.g., processing units, switches, and/or the like) of the datacenter. An optical interconnect of the plurality of optical interconnects includes a first transceiver, a second transceiver, and an optical fiber placing the first transceiver in optical communication with the second transceiver. At least one of the first transceiver or the second transceiver includes a CPM laser. The CPM laser includes an optical cavity comprising at least two gain sections, wherein a saturable absorber is disposed between adjacent gain sections of the at least two gain sections and wherein a first gain section of the at least two gain sections and a second gain section of the at least two gain sections have respective effective lengths that are equal.

Various embodiments relate to interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector or co-packaged optics. In some embodiments, the present disclosure provides optical interconnects for high bandwidth density applications like switches and GPUs or other processing elements. In one example, the processing elements may include central processing units (CPUs), graphics processing units (GPUs), data processing units (DPUs), quantum processing units (QPUs), a plurality of parallel processing units (PPUs), and application-specific integrated circuits (ASICs). QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode or multi-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally include electrical components. For instance, the device can include electrical connections for applying a potential or current to a waveguide, controlling active optical components, such as modulators, for example, and/or for controlling other components on the optical device.

### BRIEF DESCRIPTION OF THE SEVERAL VIEWS OF THE DRAWINGS

Reference will now be made to the accompanying drawings, which are not necessarily drawn to scale, and wherein:

FIG. 1A provides a schematic cross-sectional diagram of an example colliding pulse mode-locking (CPM) laser taken in a plane parallel to a surface of a substrate hosting the CPM laser, in accordance with certain embodiments;

FIG. 1B provides a schematic cross-sectional diagram of the example CPM laser shown in FIG. 1A with the cross-section taken in a plane perpendicular to the surface of the substrate and that includes an emission direction of the CPM laser, in accordance with certain embodiments;

FIG. 1C provides a schematic cross-sectional diagram of another example CPM laser taken in a plane parallel to a surface of a substrate hosting the CPM laser, in accordance with certain embodiments;

FIG. 1D provides a zoomed-in view of an end of the CPM laser illustrated in FIG. 1C, in accordance with certain embodiments;

FIG. 2A provides a flowchart illustrating various processes and/or procedures for fabricating the CPM laser illustrated in FIGS. 1A and 1B, in accordance with certain embodiments;

FIG. 2B provides a flowchart illustrating various processes and/or procedures for fabricating the CPM laser illustrated in FIG. 1C, in accordance with certain embodiments;

FIG. 3 provides a schematic cross-sectional diagram of another example colliding pulse mode-locking (CPM) laser taken in a plane parallel to a surface of a substrate hosting the CPM laser, in accordance with certain embodiments;

FIG. 4 provides a flowchart illustrating various processes and/or procedures for fabricating the CPM laser illustrated in FIG. 3, in accordance with certain embodiments;

FIG. 5 provides a schematic cross-sectional diagram of another example colliding pulse mode-locking (CPM) laser taken in a plane parallel to a surface of a substrate hosting the CPM laser, in accordance with certain embodiments;

FIG. 6 provides a flowchart illustrating various processes and/or procedures for fabricating the CPM laser illustrated in FIG. 5, according to certain embodiments;

FIG. 7 provides a schematic cross-sectional diagram of another example colliding pulse mode-locking (CPM) laser taken in a plane parallel to a surface of a substrate hosting the CPM laser, in accordance with certain embodiments;

FIG. 8 provides a flowchart illustrating various processes and/or procedures for fabricating the CPM laser illustrated in FIG. 5, according to certain embodiments;

FIG. 9 provides a block diagram of an optical interconnect including arrays of HM devices, according to certain embodiments;

FIG. 10 provides a block diagram of an example system that may include one or more optical interconnects including HM devices according to certain embodiments;

FIG. 11 provides a schematic diagram of an example datacenter that may include one or more optical interconnects according to certain embodiments;

FIG. 12 provides a block diagram of two example communication devices in communication with one another according to certain embodiments;

FIGS. 13A and 13B illustrate a top view and a perspective view, respectively, of a transceiver module operatively coupled to a network adapter, in accordance with an embodiment of the disclosure.

FIG. 14 depicts some exemplary scenarios for use of an optical transceiver, in accordance with various embodiments;

FIG. 15 provides a block diagram that schematically illustrates a computing system that may include one or more optical interconnects of various embodiments;

FIG. 16 illustrates an example computing environment, in accordance with at least one embodiment;

FIG. 17 illustrates another example computer system that may include optical interconnects, according to at least one embodiment; and

FIG. 18 is a block diagram that schematically illustrates a co-packaged Networking Device, in accordance with an embodiment that is disclosed herein.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide colliding pulse mode-locked (CPM) lasers comprising an optical cavity having segments or sections with substantially equal effective length and/or optical length and methods for fabricating CPM lasers comprising optical cavities having segments or sections of substantially equal effective lengths. As used herein, the effective length is a length L that is equal the effective mode refractive index n of the segment multiplied by the physical length d of the segment (e.g., L=nd). Some segments have multiple regions having different effective mode refractive indices. In such cases, the effective length L of a segment is a sum over the regions of the segment of the product effective mode refractive index for a region and the physical length of the region

$$( e . g . , L = {\sum }_{i} {n}_{i} {d}_{i} , where {n}_{i} is the mode effective refractive index for the ith region of the segment and {d}_{i} is the physical length of the ith region of the segment ) .$$

In some scenarios, the effective mode refractive index is wavelength dependent and therefore the corresponding effective length is wavelength dependent. In certain embodiments the effective length of the segments or sections of the optical cavity are within 1% of one another. In some embodiments, the CPM lasers may be incorporated into optical interconnects (e.g., as optical signal generating components, optical signal detecting components, and/or the like).

In various embodiments, a CPM laser is configured to generate frequency comb laser pulses comprising a plurality of teeth or spectral lines. The teeth or spectral lines of the frequency comb laser pulses may be used as the optical carriers for performing coarse and/or dense wavelength division multiplexing (WDM). One technique to create a comb laser is a colliding pulse mode-locking (CPM) method where two or more counter-propagating pulses collide at a specific location within an optical cavity, typically at a saturable absorber. These interactions can enhance pulse shortening and stability due to pulses reinforcing each other's peak intensity at the collision point within the optical cavity. In this technique instead of a single pulse circulating in the optical cavity, multiple pulses are generated in the cavity such that they are spaced evenly along the round-trip path.

When CPM is harmonically mode-locked, multiple pulse pairs collide within a single round trip, effectively increasing the frequency of pulse collisions and thereby increasing the repetition rate. For example, at the second harmonic, two pairs of counter-propagating pulses collide per round trip, doubling the effective repetition rate. The higher repetition rate by harmonic mode locking does not change the underlining physics of the comb laser, it simply adds more collision events per unit time. However, by introducing harmonics the stability of the system may become more challenging to maintain, as the cavity setup needs precise alignment to manage multiple pulses to interfere constructively.

In CPM it is imperative that the propagating pulses in the cavity meet at the saturable absorber sections. Conventionally, traditional cleaving of samples sets the effective length of the segments or sections of the CPM optical cavity. However, traditional cleaving precision is not sufficient to ensure efficient harmonic generation. For example, traditional cleaving precision may result in segments or sections of the optical cavity having effective lengths that differ by as much as 5%. Therefore, technical challenges exist regarding providing CPM lasers having optical cavity segments or sections with substantially equal effective lengths such that the CPM lasers are configured to provide frequency comb laser pulses in an energy efficient manner.

Various embodiments provide technical solutions to these technical problems. For example, various embodiments provide methods for fabricating CPM lasers including optical cavities having segments or sections with effective lengths that are within 1% of one another. In some embodiments, the effective length of the segments or sections of the optical cavity are within 0.01% of one another. These CPM lasers may be incorporated into optical interconnects and/or other systems, used as coarse or dense WDM sources, and/or the like. Therefore, various embodiments provide improvements to the fields of CPM lasers, optical communications, and/or the like.

### Example CPM Lasers and Methods for Fabrication Thereof

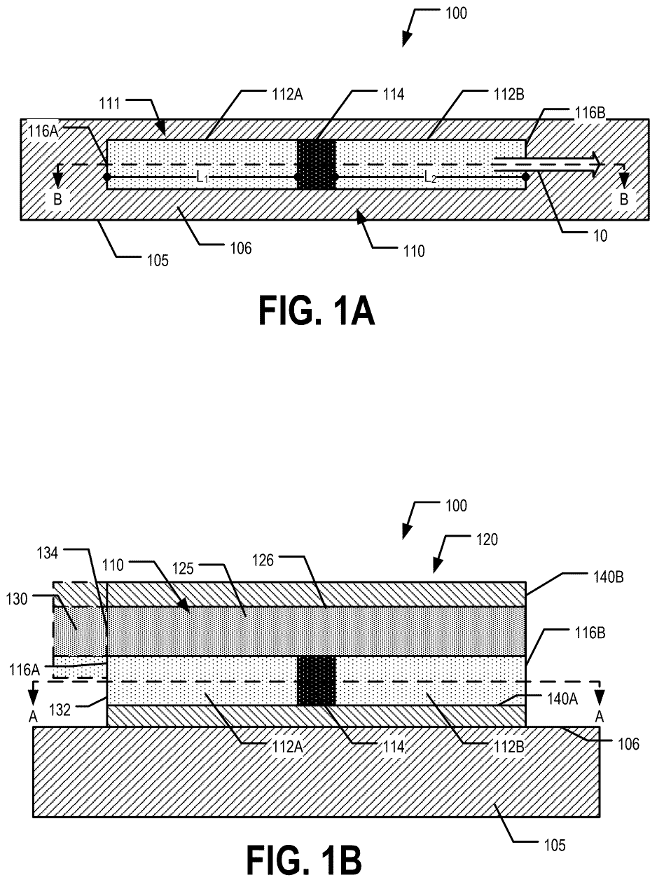

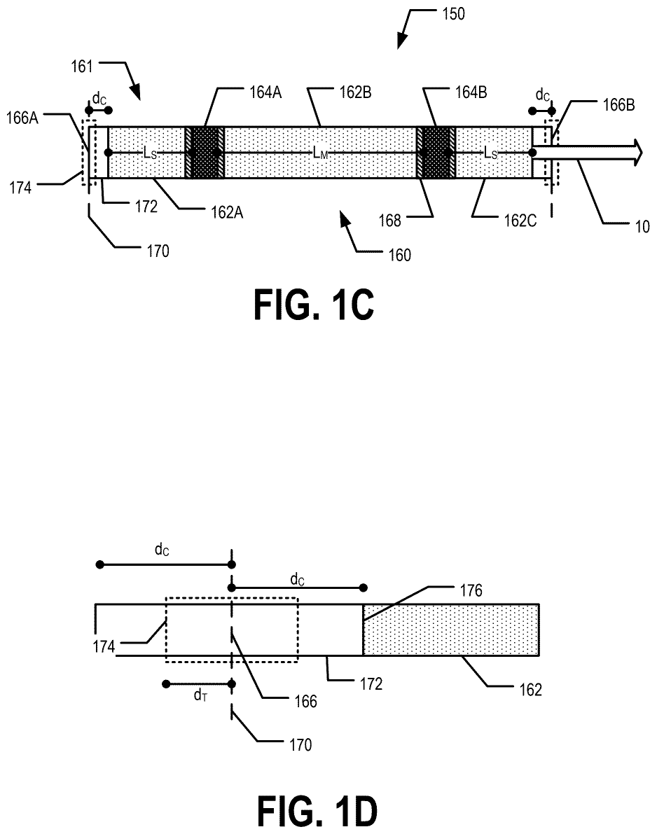

FIG. 1A provides a schematic cross-sectional diagram illustrating an example CPM laser 100 with the cross-section taken in a plane through the active region 111 of the optical cavity 110 of the CPM laser that is parallel to a surface 106 of a substrate 105 on which the CPM laser 100 is fabricated and/or disposed. FIG. 1B provides a schematic cross-sectional diagram of the CPM laser 100 taken in a plane that includes the emission direction 10 and that is perpendicular to the surface 106 of the substrate 105 on which the CPM laser 100 is fabricated and/or disposed. For example, the cross-section of the CPM laser 100 shown in FIG. 1A is taken along the AA line shown in FIG. 1B and the cross-section of the CPM laser 100 shown in FIG. 1B is taken along the BB line shown in FIG. 1A.

The CPM laser 100 comprises an optical cavity 110 that is divided into two or more gain segments or sections 112 (e.g., 112A, 112B). In an example embodiment, adjacent gain segments or sections 112A, 112B are spatially separated from one another by a saturable absorber 114. For example, the saturable absorber 114 is disposed between the first gain segment or section 112A and the second gain segment and/or section 112B. In various embodiments, the gain segments or sections 112 comprise a gain or active material configured to generate light. For example, the gain segments or sections 112 may comprise an active material and/or semiconductor material comprising quantum wells configured to generate light. In various embodiments, the gain segments or sections 112 comprise an active material that includes a quantum confined material selected from the group consisting of: quantum wells (QW), quantum dots (QD), and quantum dashes (QDash). For example, for high-repetition-rate operation (e.g., >100 GHz or >200 GHz), the gain segments or sections 112 comprise quantum dot layers configured to provide high gain density with low linewidth enhancement factor, thereby stabilizing the mode-locking mechanism despite the shortened cavity length, in certain embodiments. In some embodiments, the active material includes a combination (e.g., two or more) of QWs, QDs, and/or QDashes.

The optical cavity 110 is defined by a first end 116A and a second end 116B. For example, the CPM laser 100 may emit light (e.g., in the form of frequency comb laser pulses) via the second end 116B. In another example, the first end 116A may be reflective so as to maintain optical power within the optical cavity 110. For example, the first end 116A may be configured to be highly reflective and reflect more than 50% (e.g., more than 75%, more than 80%, more than 90%, more than 95%, more than 99%) of light incident thereon from within the waveguide structure 125 back into the waveguide structure 125. In various embodiments, the second end 116B may be partially reflective.

As shown in FIG. 1B, the optical cavity 110 is part of a ridge waveguide 120 comprising a waveguide structure 125. The waveguide structure 125 is in optical communication with the active region 111 via a surface 126 of the waveguide structure 125. For example, the waveguide structure 125 may be a waveguide configured to support one or more guided modes and/or to contain/confine light therein. In some embodiments, the ridge waveguide 120 further includes one or more layers of cladding 140A, 140B disposed between the active region 111 and the substrate 105 and/or on a surface of the waveguide structure 125 that is opposite the surface of the waveguide structure 125 that is in optical communication with the active region 111.

The first gain segment or section 112A has a first effective length L₁ and the second gain segment or section 112B has a second effective length L₂. The first effective length L₁ is substantially equal to the second optical L₂ and/or a harmonic thereof. For example, In some embodiments, the first effective length L₁ is substantially equal to the second optical L₂ (e.g., L₁=L₂). In certain embodiments, the optical cavity may include three gain segments or sections (e.g., a left section, middle section, and right section). In such embodiments, the physical length of the left section and the right section may be half of the physical length of the middle section such that the double pass of a pulse in the left section and right section results in all three sections having equal optical lengths. As used herein, the effective lengths of the gain segments or sections are substantially equal to one another when the pulse travel time is consistent and/or uniform for each gain segment or section. For example, the pulse travel time in the first gain segment or section is the same as the pulse travel time in the second gain segment or section.

FIG. 1C provides a schematic cross-sectional view diagram illustrating another example CPM laser 150 where the cross section is taken in a plane through the active region 161 of the optical cavity 160 of the CPM laser 150 that is parallel to a surface of a substrate (not shown) on which the CPM laser 150 is fabricated and/or disposed.

At least one end of the optical cavity 160 is defined via cleaving. In order to perform the cleaving, a cleaving section 172 is formed and/or defined. In certain embodiments, the cleaving section 172 is a BCB-free zone or polymer-free region through which the cleaving is performed, for cleaving. Conventionally, the optical cavity of a semiconductor laser with an optical cavity defined via cleaving is treated as ending at the interface 176 between the cleaving section 172 and the adjacent gain segment or section 162A, 162C.

The CPM laser 150 comprises an optical cavity 160 that is divided into three gain segments or sections 162 (e.g., 162A, 162B, 162C). Various embodiments may include various numbers of gain segments or sections 162 (e.g., two or more gain segments or sections). In an example embodiment, adjacent gain segments or sections 162A, 162B, 162C are spatially separated from one another by a saturable absorber 164 and trenches 168 configured to electrically isolate the saturable absorber 164 from the gain material of the gain segments or sections 162. For example, the saturable absorber 164A is disposed between the first gain segment or section 162A and the second gain segment and/or section 162B and the saturable absorber 164B is disposed between the second gain segment or section 162B and the third gain segment and/or section 162C. In various embodiments, the gain segments or sections 162 comprise a gain or active material configured to generate light. For example, the gain segments or sections 162 may comprise an active material and/or semiconductor material comprising quantum wells configured to generate light.

The optical cavity 160 is defined by a first end 166A and a second end 166B. For example, the CPM laser 600 may emit light (e.g., in the form of frequency comb laser pulses) via the second end 166B. In another example, the first end 166A may be reflective so as to maintain optical power within the optical cavity 160. For example, the first end 166A may be configured to be highly reflective and reflect more than 50% (e.g., more than 75%, more than 80%, more than 90%, more than 95%, more than 99%) of light incident thereon from within the waveguide structure back into the waveguide structure. In various embodiments, the second end 166B may be partially reflective. For example, the first end 166A may be a cleaved end, possibly with a reflectivity coating applied thereto. The second end 166B may be cleaved end configured to enable partial transmission therethrough.

In various embodiments, the optical cavity 160 is part of a ridge waveguide (similar to that shown in FIG. 1B) comprising a waveguide structure. The waveguide structure is in optical communication with the active region 161 via a surface of the waveguide structure. For example, the waveguide structure may be a waveguide configured to support one or more guided modes and/or to contain/confine light therein. In some embodiments, the ridge waveguide further includes one or more layers of cladding disposed between the active region 161 and the substrate on which the CMP laser 150 is formed/disposed and/or on a surface of the waveguide structure that is opposite the surface of the waveguide structure that is in optical communication with the active region 161.

The second optical cavity segment (e.g., the second gain segment or section 162B) has a middle segment effective length L_{M}. The first and third optical cavity segments (which include the gain segments or sections 162A, 162C, respectively) are configured to have a round trip time that is equal to a one way trip time of the second optical cavity segment (e.g., the second gain segment or section 162B). In other words, the time required for light to travel from the first saturable absorber 164A to the first end 166A and back to the first saturable absorber 164A, which is (approximately and/or substantially) the same as the time required for light to travel from the second saturable absorber 164B to the second end 166B and back to the second saturable absorber 164B, is (approximately and/or substantially) the same as the required for light to travel from the first saturable absorber 164A to the second saturable absorber 164B (or vice versa).

In various embodiments, the end 166 of the optical cavity 160 is defined at least in part by cleaving. FIG. 1D illustrates a close up of an end 166 of the optical cavity illustrating the location of the cleaving mark line 170. The cleaving mark line 170 indicates where the cleaving should be performed to define the end 166. However, as a result of the accuracy of cleaving procedures being within a tolerance length L_{T}, the cleaving is expected to define the end 166 at some location within the dotted box 174. In some embodiments, the tolerance distance d_{T} is +/−5 microns (the tolerance distance corresponds to an effective tolerance length L_{T} that is equal to the physical tolerance distance d_{T} multiplied by the refractive index n_{C} of the material of the cleaving section 172). As such, the cleaving is not performed at the end of the gain segment or section 162. Rather, a cleaving section 172 is added to the end of the gain segment or section 162. In various embodiments, the cleaving section 172 comprises the same material as the gain segment or sections 162, but without a P contact and possibly without cladding or BCB disposed thereon.

For example, the optical cavity may include a first optical cavity segment that includes the cleaving section 172 and the first gain segment or section 162A located between the first end 166A and the first saturable absorber 164A, a second optical cavity segment that includes the second gain segment or section 162B between the first saturable absorber 164A and the second saturable absorber 164B, and a third optical cavity segment that includes the third gain segment or section 162C and the cleaving section 172 located between the second saturable absorber 164B and the second end 166B.

The cleaving section 172 has a length such that the distance between the end of the gain segment or section 166 and the cleaving mark line 170 is a cleaving length L_{C}. The cleaving distance d_{c} is configured to enable cleaving of the ridge waveguide. For example, the cleaving section 172 may not include cladding/BCB/polymer above the active region 160. For example, the CMP laser 150 is formed as part of a ridge waveguide with cladding (e.g., BCB and/or the like) disposed between the active region 160 and the external “top” surface of the ridge waveguide. However, the cladding may not be present in the cleaving section such that the cleaving can be performed more cleanly and more accurately (compared to if the cleaving were performed through a layer of cladding). In some embodiments, the cleaving section 172 has a length that is twice the cleaving length L_{C}. In various embodiments, the cleaving distance d_{C} is in a range of 5 to 15 microns (e.g., 10 microns). As should be understood, the cleaving distance d_{C} and the tolerance distance d_{T} may vary based on the cleaving procedure to be used to performing the cleaving that defines the end 166.

When the cleaving is performed along the cleaving line mark 170, the physical length of the cleaving section that remains as part of the optical cavity is the cleaving distance d_{C}. Therefore, the amount of time required for light to travel from the first saturable absorber 164A to the first end 166A and back to the first saturable absorber 164A is dependent on the effective cleaving length L_{C} which is the physical cleaving distance d_{C} multiplied by the refractive index n_{C} of the cleaving section 172 (e.g., L_{C}=d_{C}*n_{C}). For example, the light has to traverse the side section effective length L_{S} and the effective cleaving length L_{C} to reach the first end 166A from the first saturable absorber 164A and then traverse the effective cleaving length L_{C} and the effective length of the side section L_{S} to return to the first saturable absorber 164A. Therefore, in some embodiments, the side section effective length L_{S} is determined and/or set such that 2*(L_{S}+L_{C})=L_{M}, where L_{M} is the middle gain section effective length—the effective length of the middle gain segment or section 162B (e.g., the effective distance between the first saturable absorber 164A and the second saturable absorber 164B). In other words, the side section effective length L_{S} is determined based at least in part on the effective cleaving length L_{C} and/or the physical cleaving distance d_{C} of the cleaving process

As should be understood, the actual cleaving that defines the end 166 of the optical cavity 160 may be anywhere within the dotted box 174. In other words, the true effective length between the first saturable absorber 164A and the first end 166A, for example, may differ from the ideal effective length L_{S}+L_{C} by the effective tolerance length +/−L_{T}. However, as the physical cleaving distance d_{C} is configured to be larger than the physical tolerance distance d_{T} (e.g., by a factor of two in some embodiments). Thus, the error introduced by the difference between the true effective length (e.g., the actual effective length after the cleaving is performed) and the ideal effective length (e.g., the planned effective length) between the end 166 of the optical cavity and the adjacent saturable absorber (e.g., the distance between the first end 166A and the first saturable absorber 164A or the distance between the second end 166B and the second saturable absorber 164B) is small.

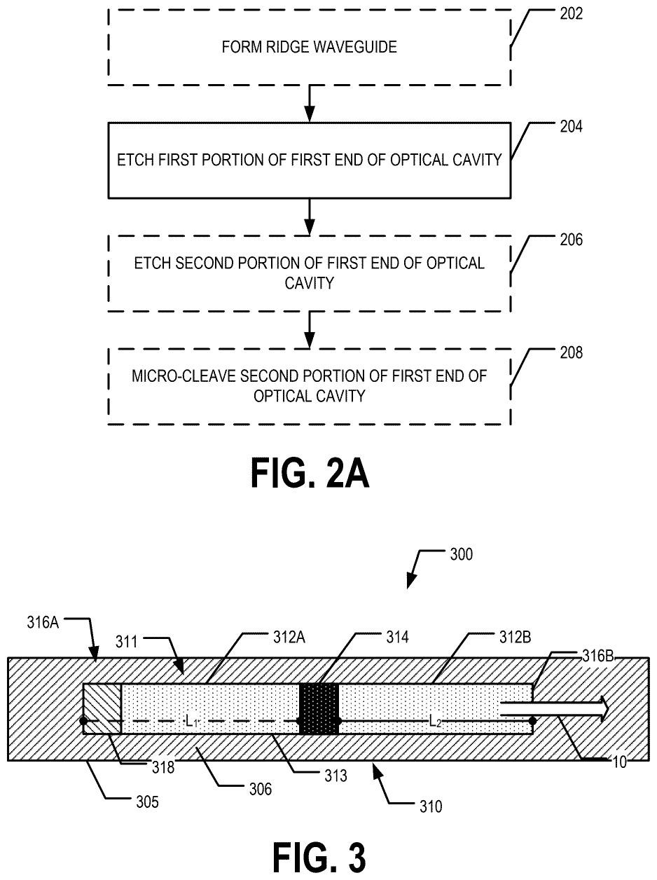

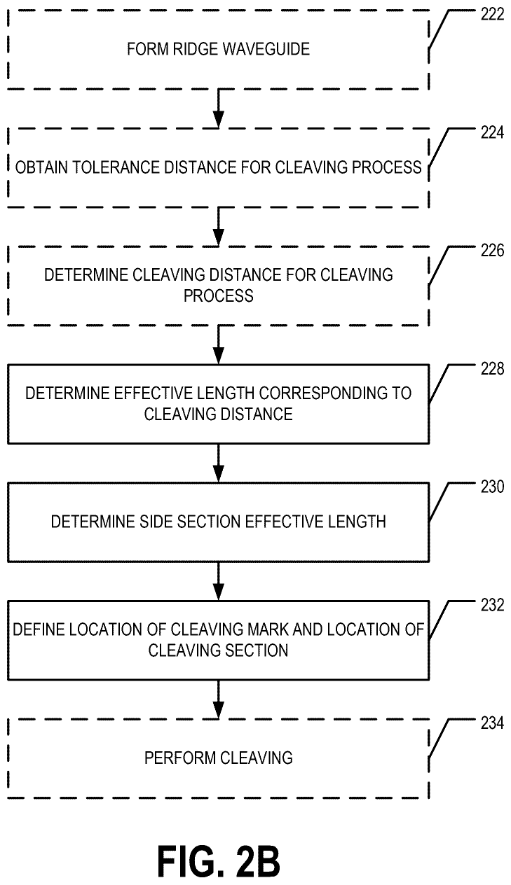

FIG. 2A provides a flowchart illustrating various processes and/or procedures for fabricating a CPM laser 100. Starting at block 202, a ridge waveguide 120 is fabricated on a substrate 105. For example, a first cladding 140A may be deposited on the substrate 105. The active region 111 may be epitaxially grown on the first cladding 140A. A saturable absorber 114 may be formed in the active region 111 (e.g., via trenching edges or a perimeter of the saturable absorber 114 in the active material grown to form the active region 111. A waveguide structure 125 may be fabricated on the active region. For example, material of the waveguide structure 125 may be deposited and/or grown on the active region 111. In some embodiments, a second cladding 140B may be deposited on the waveguide structure 125. In various embodiments, one or more electrical contacts and/or pads may be deposited and/or patterned. The ridge waveguide 120 may be fabricated using various techniques, as appropriate for the application.

In various embodiments, forming the saturable absorber 114 includes electrically isolating the portion of the active material of the active region 111 to be used as the saturable absorber from the gain segments or sections 112. For example, trenches (e.g., similar to trenches 168) may be formed to electrically isolate the saturable absorber 144 from the gain segments or sections 112. The patterning of the electrical contacts and/or pads may include defining electrodes configured for injecting current into the saturable absorber 114. For example, during operation of the CPM 100, current may be injected into the saturable absorber 114 such that the active material of the saturable absorber 114 has a high (electric charge) carrier density (e.g., becomes saturated).

At block 204, a first portion 132 of the first end 116A of the optical cavity is defined via etching. For example, a lithographic etch may be performed on the first portion 132 of the first end 116A. For example, at least a first portion 132 of the first end 116A is etched (e.g., through at least a portion of a first gain segment or section 112A) to define the first effective length L₁ of the first gain section 112A. For example, the second effective length L₂ may be defined via formation of the second end 116B during the fabrication of the ridge waveguide 120. The etching of the first portion 132 of the first end 116A may be performed such that the first effective length L₁ is substantially equal to the second effective length L₂ (or a harmonic thereof).

At block 206, in certain embodiments, a second portion 134 of the first end 116A of the optical cavity is defined via etching. For example, a lithographic etch may be performed on the second portion 134 of the first end 116A. In some embodiments, the first portion 132 and the second portion 134 of the first end 116A are etched via the same etching process. For example, block 204 and block 206 may be performed as a continuous process rather than as two distinct or separate steps.

At block 208, in certain embodiments, a second portion 134 of the first end 116A of the optical cavity is defined via micro-cleaving. For example, as a result of block 204, a cantilevered portion 130 of the ridge waveguide 120 is formed. The cantilevered portion 130 may be micro-cleaved to define the second portion 134 of the first end 116A. For example, ultrasonic vibrations may be applied to the cantilevered portion 130 and/or the ridge waveguide 120 by using an acousto-optic modulator. In various embodiments, the ultrasonic vibrations are characterized by a wavelength that is resonant with the cantilevered portion 130. As a result of the ultrasonic vibrations being applied to the cantilevered portion 130 and/or the ridge waveguide 120, the cantilevered portion cleaves from the remainder of the ridge waveguide 120 along a crystal face exposed via the etching of the first portion 132 of the first end 116A of the optical cavity 110. For example, applying the ultrasonic vibrations to the cantilevered portion 130 and/or the ridge waveguide 120 causes an unetched portion (e.g., the second portion 134) of the first end 116A of the optical cavity to cleave at a crystal face corresponding to the first portion 132 of the first end 116A. The length of the cantilever may be related to the frequency of the ultrasonic waves for efficient cleaving. In various embodiments, the second portion 134 of the first end 116A includes an end or a boundary of the waveguide structure 125. In some embodiments, the micro-cleaving of the second portion 134 of the first end 116A results in a smooth and/or reflective surface on the second portion 134 of the first end 116A that is accurately placed such that the first effective length L₁ is substantially equal to the second effective length L₂ (or a harmonic thereof).

In some embodiments, a reflective coating may be applied to the first end 116A to increase the reflectivity thereof.

As a result of the accuracy of the placement of the first end 116A (e.g., using a lithographic process to etch at least the first portion 132 of the first end 116A), the first effective length L₁ is equal to the second effective length L₂ with tighter tolerance compared to when the first end 116A is defined via traditional cleaving processes.

FIG. 2B provides a flowchart illustrating various processes and/or procedures for fabricating a CPM laser 150. Starting at block 222, a ridge waveguide (e.g., similar to ridge waveguide 120) is fabricated on a substrate (e.g., similar to substrate 105). For example, a first cladding (e.g., similar to cladding 140A) may be deposited on the substrate. The active region 161 may be epitaxially grown on the first cladding. A saturable absorber 164 may be formed in the active region 161 (e.g., via trenching edges or a perimeter of the saturable absorber 164 in the active material grown to form the active region 161 to form trenches 168). A waveguide structure (e.g., similar to waveguide structure 125) may be fabricated on the active region. For example, material of the waveguide structure may be deposited and/or grown on the active region 161. In some embodiments, a second cladding (e.g., similar to cladding 140B) may be deposited on the waveguide structure. In various embodiments, one or more electrical contacts and/or pads may be deposited and/or patterned. The ridge waveguide may be fabricated using various techniques, as appropriate for the application. The second cladding may be patterned to define the cleaving section 172 between performance of blocks 232 and 234.

In various embodiments, forming the saturable absorber 164 includes electrically isolating the portion of the active material of the active region 161 to be used as the saturable absorber from the gain segments or sections 162. For example, trenches 168 may be formed to electrically isolate the saturable absorber 164 from the gain segments or sections 162. The patterning of the electrical contacts and/or pads may include defining electrodes configured for injecting current into the saturable absorber 164. For example, during operation of the CPM 150, current may be injected into the saturable absorber 164 such that the active material of the saturable absorber 164 has a high (electric charge) carrier density (e.g., becomes saturated).

At block 224, a tolerance distance for a cleaving process to be used is obtained. For example, the tolerance distance d_{T} may be determined empirically, from one or more data source regarding the cleaving process, ad hoc information, and/or the like. At block 226, a cleaving distance is determined for the cleaving process. In various embodiments, the cleaving distance d_{C} is determined to be greater than the tolerance distance d_{T}. For example, the cleaving distance d_{C} is to be determined to be twice the tolerance distance d_{T} (e.g., d_{C}=2d_{T}), in certain embodiments. In some embodiments, an effective length corresponding to the cleaving distance L_{C} is determined, at block 228. In an example embodiment, the effective length corresponding to the cleaving distance L_{C} is equal to the cleaving distance d_{C} multiplied by the refractive index of the cleaving section n_{C}.

At block 230, a side section effective length L_{S} is determined based at least in part on the cleaving distance L_{C}. In an example embodiment, the side section effective length L_{S} is determined such that 2*(L_{S}+L_{C})=L_{M}, where L_{M} is the middle segment effective length. The physical distance d_{S} corresponding to the side section effective length L_{S} may then be determined such that the physical distance d_{S} multiplied by the refractive index n_{g} of the gain segments or sections 162A, 162B, 162C is equal to the side section effective length L_{S} (e.g., L_{S}=n_{g}*d_{S}).

Based at least in part on the physical distance d_{S} corresponding to the side section effective length L_{S} and the cleaving distance d_{C}, a location of the cleaving mark 170 is determined. The cleaving mark 170 indicates a long which the cleaving is intended to be performed. The location of the cleaving section 172 (e.g., the location of the interface 176) is also determined based on the physical distance d_{S} corresponding to the side section effective length L_{S} and the cleaving distance d_{C}.

In various embodiments, the second cladding formed on the ridge waveguide may be patterned to define the cleaving section 172. For example, any cladding, BCB, polymer, and/or the like present in the cleaving section 172 may be removed. In some embodiments, the location of the cleaving section 172 is defined prior to the deposition of the second cladding and the cleaving section 172 is formed via a lift-off process. In some embodiments, BCB, polymer, and/or the like may be present in the cleaving section 172 and removed from along the cleaving mark 170 (e.g., the line along which the cleaving is intended to be performed). In some embodiments, the cleaving may be performed through the BCB, polymer, and/or the like.

At block 234, the cleaving is performed. For example, the cleaving process is performed to cause cleaving of ridge waveguide (e.g., the cleaving section 172) substantially along the cleaving mark 170 (e.g., with the threshold distance d_{T} of the cleaving mark 170).

In various embodiments, at least portions of blocks 224-232 are performed by a computing entity such as a desktop computer, laptop computer, tablet, server, blade, switch, and/or other computing device.

FIG. 3 provides a schematic cross-sectional diagram illustrating an example CPM laser 300 with the cross-section taken in a plane through the active region 311 of the optical cavity 310 of the CPM laser 300 that is parallel to a surface 306 of a substrate 305 on which the CPM laser 300 is fabricated and/or disposed. For example, the active region 311 may be part of a ridge waveguide similar to ridge waveguide 120 that includes a waveguide structure in optical communication with the active region 311 via a surface of the waveguide structure and one or more layers of cladding (e.g., a first cladding disposed between substrate 305 and the active region 311 and a second cladding on a surface of a waveguide structure that is opposite the surface via which the waveguide structure is in optical communication with the active region 311).

The CPM laser 300 comprises an optical cavity 310 that is divided into two or more gain segments or sections 312 (e.g., 312A, 312B). In an example embodiment, adjacent gain segments or sections 312A, 312B are spatially separated from one another by a saturable absorber 314. For example, the saturable absorber 314 is disposed between the first gain segment or section 312A and the second gain segment and/or section 312B. In various embodiments, the gain segments or sections 312 comprise a gain or active material configured to generate light. For example, the gain segments or sections 312 may comprise an active material and/or semiconductor material comprising quantum wells configured to generate light.

The optical cavity 310 is defined by a first end 316A and a second end 316B. For example, the CPM laser 300 may emit light (e.g., in the form of frequency comb laser pulses) via the second end 316B. In another example, the first end 316A may be reflective so as to maintain optical power within the optical cavity 310. For example, the first end 316A may be configured to be highly reflective and reflect more than 50% (e.g., more than 75%, more than 80%, more than 90%, more than 95%, more than 99%) of light incident thereon from within the waveguide structure of the CPM laser 300 back into the waveguide structure. In various embodiments, the second end 316B may be partially reflective.

In various embodiments a first end 316A of the optical cavity 310 is defined by a saturated gain phase change section 318. In various embodiments, the saturated gain phase change section 318 may include the same active and/or semiconductor material that is electrically separated from a remainder of the first gain segment or section 312A such that the saturated gain phase change section may be independently biased. For example, the saturated phase change section 318 may be forward biased with respect to the first gain segment or section 312A. In various embodiments, the voltage applied to the saturated gain phase change section 318 may be tuned to tune the first effective length L₁ of the first gain segment or section 312A. For example, the first effective length L₁ may be dynamically adjustable or tunable during operation of the CPM laser 300 by controlling the voltage applied to the saturated gain phase change section 318. For example, the voltage applied to the saturated gain phase change section 318 controls the amount of phase accumulated by light propagating through the saturated gain phase change section 318, thereby effectively changing the effective length of the first gain segment or section 312A. In some embodiments, the second gain segment or section 312B additionally or alternatively includes a saturated gain phase change section 318 such that the second effective length L₂ of the second gain segment or section 312B is dynamically adjustable or tunable during operation of the CPM laser 300.

The first gain segment or section 312A is characterized by a first effective length L₁ and the second gain segment or section 312B has a second effective length L₂. The first effective length L₁ is tunable such that the first effective length L₁ is substantially equal to the second optical L₂ and/or a harmonic thereof. For example, In some embodiments, the first effective length L₁ is tunable such that the first effective length L₁ is substantially equal to the second optical L₂ (e.g., L₁=L₂).

In certain embodiments, the optical cavity may include three gain segments or sections (e.g., a left section, middle section, and right section). In such embodiments, the physical length of the left section and the right section may be half of the physical length of the middle section such that the double pass of a pulse in the left section and right section results in all three sections having equal optical lengths. As used herein, the effective lengths of the gain segments or sections are substantially equal to one another when the pulse travel time is consistent and/or uniform for each gain segment or section. For example, the pulse travel time in the first gain segment or section is the same as the pulse travel time in the second gain segment or section.

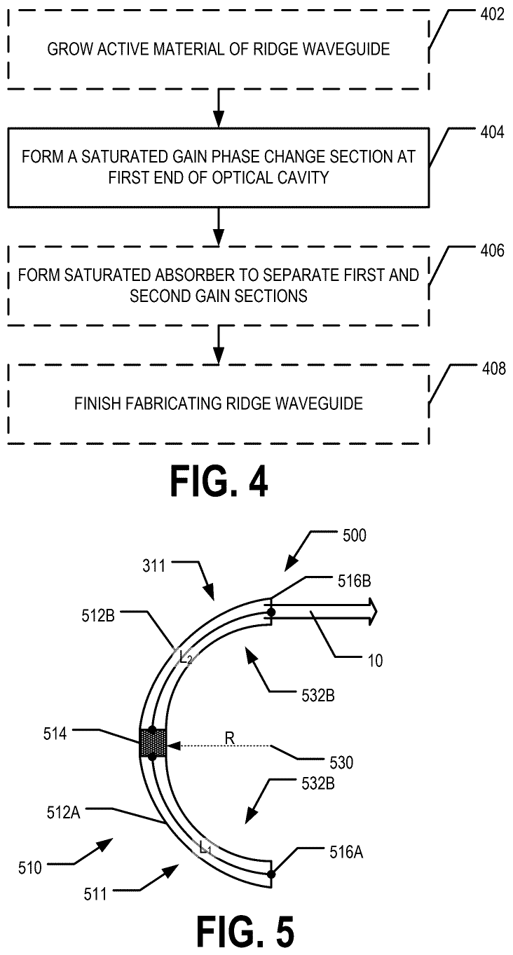

FIG. 4 provides a flowchart illustrating various processes and/or procedures for fabricating a CPM laser 300. Starting at block 402, a portion of a ridge waveguide is fabricated on a substrate 305. For example, a first cladding may be deposited on the substrate 305. The active material of the active region 311 may be epitaxially grown on the first cladding.

At block 404, a saturated gain phase change section 318 is formed at the first end 316A of the optical cavity 310. For example, the active material of the active region 311 may be trenched to electrically isolate the saturated gain phase change section 318 from the gain region 313 of the first gain segment or section 312A. For example, an isolation trench may be formed or etched to form the saturated gain phase change section 318. In some embodiments, a reflective coating may be applied to the first end 316A to increase the reflectivity thereof.

At block 406, a saturable absorber 314 is formed to define the first gain segment or section 312A and the second gain segment or section 312B. For example, the active material of the active region 311 may be trenched to electrically isolate the saturable absorber from the first gain segment or section 312A and the second gain segment or section 312B. For example, isolate trenches may be formed or etched in the gain material to define the first edge and second edge of the saturable absorber 314.

In various embodiments, block 404 may be performed before performance of block 406. In certain embodiments, block 406 may be performed before performance of block 404. In some embodiments, block 404 and block 406 are performed at the same time and/or simultaneously. For example, the trench(es) used to define and/or form the saturated gain phase change section 318 and the trenches used to define and/or form the saturable absorber 314 may be formed via the same etching process.

At block 408, a remainder of the ridge waveguide is fabricated. For example, a waveguide structure may be fabricated on the active region 311. For example, material of the waveguide structure may be deposited and/or grown on the active region 311. In some embodiments, a second cladding may be deposited on the waveguide structure. In various embodiments, one or more electrical contacts and/or pads may be deposited and/or patterned. For example, electrical contacts and/or pads may be fabricated for applying respective voltages to the saturated gain phase change section 318, the saturable absorber 314, and the gain segments and/or sections 312. The ridge waveguide may be fabricated using various techniques, as appropriate for the application.

FIG. 5 provides a schematic cross-sectional diagram illustrating an example CPM laser 500 with the cross-section taken in a plane through the active region 511 of the optical cavity 510 of the CPM laser 500 that is parallel to a surface of a substrate (not shown) on which the CPM laser 500 is fabricated and/or disposed. For example, the active region 511 may be part of a ridge waveguide similar to ridge waveguide 120 that includes a waveguide structure in optical communication with the active region 511 via a surface of the waveguide structure and one or more layers of cladding (e.g., a first cladding disposed between substrate and the active region 511 and a second cladding on a surface of a waveguide structure that is opposite the surface via which the waveguide structure is in optical communication with the active region 511).

The CPM laser 300 comprises an optical cavity 510 that is divided into two or more gain segments or sections 512 (e.g., 512A, 512B). In an example embodiment, adjacent gain segments or sections 512A, 512B are spatially separated from one another by a saturable absorber 514. For example, the saturable absorber 514 is disposed between the first gain segment or section 512A and the second gain segment and/or section 512B. In various embodiments, the gain segments or sections 512 comprise a gain or active material configured to generate light. For example, the gain segments or sections 512 may comprise an active material and/or semiconductor material comprising quantum wells configured to generate light.

The optical cavity 510 is C-shaped. For example, The optical cavity 510 is characterized by a radius of curvature R, with respect to reference point 530, that is greater than zero. For example, the optical cavity 510 includes two curved arms 532 (e.g., 532A, 532B) that are each defined by a respective optical cavity end 516A, 516B and that meet at a saturable absorber 514. For example, the saturable absorber 514 may be disposed at a central point of the curve of the C-shaped optical cavity 510. The arms 532A, 532B are curved such that the ends 516A, 516B of the optical cavity are disposed in the same plane (e.g., a plane perpendicular to a surface of the substrate on which the CPM laser 500 is fabricated). In various embodiments, the ends 516A, 516B of the optical cavity 510 are formed during a same cleaving process such that the cleaving of the ends 516A, 516B occurs at the same crystal face.

In various embodiments, the radius of curvature R is configured to minimize optical loss of the optical cavity 510 while maintaining the distance between the two ends 516A, 516B at less than a threshold distance. For example, the threshold distance may be selected such that the cleaving process used to simultaneously form and/or define the ends 516A, 516B is likely to cleave both ends along the same crystal face. In some embodiments, the radius of curvature R is determined and/or configured based at least in part on the mode diameter(s) of the confined mode(s) of the optical cavity 510.

For example, the CPM laser 500 may emit light (e.g., in the form of frequency comb laser pulses) via the second end 516B. In various embodiments, the first end 516A may be reflective so as to maintain optical power within the optical cavity 510. For example, the first end 516A may be configured to be highly reflective and reflect more than 50% (e.g., more than 75%, more than 80%, more than 90%, more than 95%, more than 99%) of light incident thereon from within the waveguide structure of the CPM laser 500 back into the waveguide structure. In various embodiments, the second end 516B may be partially reflective. For example, the reflectivity of the second end 516B (through which the CPM laser lases) may be in a range of 1 to 99%, in various embodiments.

The first gain segment or section 512A has a first effective length L₁ and the second gain segment or section 512B has a second effective length L₂. The first effective length L₁ is substantially equal to the second optical L₂ and/or a harmonic thereof. For example, in some embodiments, the first effective length L₁ is substantially equal to the second optical L₂ (e.g., L₁=L₂). In certain embodiments, the first effective length L₁ is substantially equal to half the second effective length L₂ or vice versa (e.g., L₁=L₂/2 or L₁/2=L₂). As used herein, two values are substantially equal to one another when the difference between the two values is no more than 1% of the smaller value. In some embodiments, the effective lengths of the gain segments or sections 512 are determined based at least in part on an effective length corresponding to a cleaving distance of a cleaving process used to define the ends 516A, 516B of the optical cavity 510.

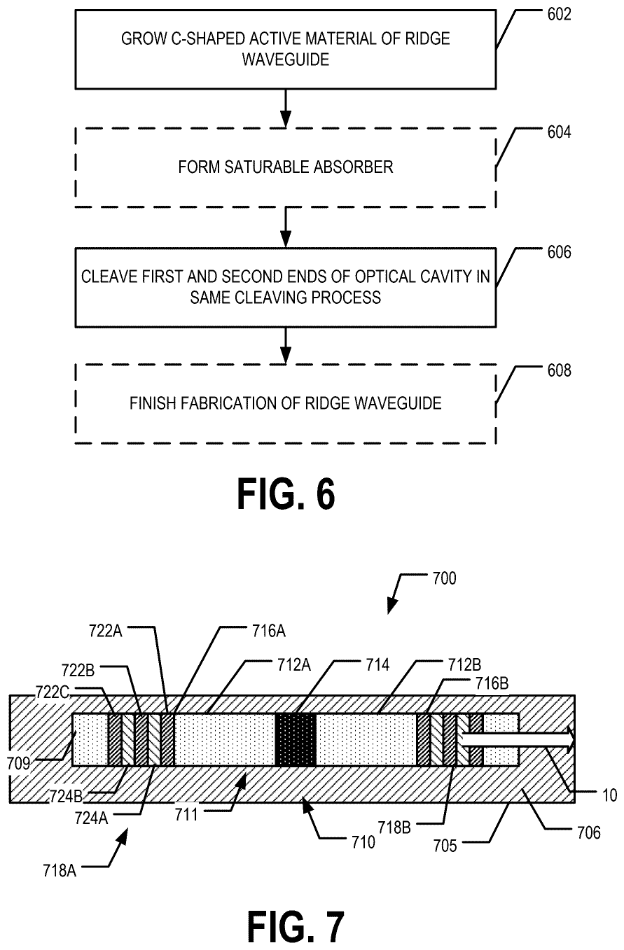

FIG. 6 provides a flowchart illustrating various processes and/or procedures for fabricating a CPM laser 500. Starting at block 602, a portion of a curved or C-shaped ridge waveguide is fabricated on a substrate. For example, a first cladding may be deposited on the substrate. The active material of the curved active region 511 may be epitaxially grown on the first cladding. In various embodiments, the active material may be grown or patterned to have a curved or C-shape. For example, the active material may be grown or patterned to include two arms that curve away from a central point of the active region 511 with a non-zero radius of curvature R.

At block 604, a saturable absorber 514 is formed to define the first gain segment or section 512A and the second gain segment or section 512B. For example, the active material of the active region 511 may be trenched to electrically isolate the saturable absorber from the first gain segment or section 512A and the second gain segment or section 512B. In various embodiments, the saturable absorber 514 is defined at a central point in the curved active region 511.

At block 606, a cleaving process is performed to define the first end 516A and the second end 516B of the optical cavity 510 in the same cleaving process. For example, a single cleaving process may be performed to cleave the first end 516A and the second end 516B along the same crystal face of the active material. In an example embodiment, the cleaving process is configured to be performed as a micro-cleaving process where a notch is etched (e.g., using a lithographic etching technique) and then ultrasonic vibrations are applied to cause cleaving of the active material along the desired crystal face. In an example embodiment, the cleaving process is a conventional cleaving process. In some embodiments, a reflective coating may be applied to the first end 516A (e.g., to increase the reflectivity thereof).

In various embodiments, block 604 may be performed before performance of block 606. In certain embodiments, block 606 may be performed before performance of block 604.

At block 608, a remainder of the curved and/or C-shaped ridge waveguide is fabricated. For example, a curved or C-shaped waveguide structure may be fabricated on the active region 511. For example, material of the waveguide structure may be deposited and/or grown on the active region 511 and be grown, deposited, and/or patterned to have a curvature of the radius of curvature R. In some embodiments, a second cladding may be deposited on the curbed or C-shaped waveguide structure. In various embodiments, one or more electrical contacts and/or pads may be deposited and/or patterned. For example, electrical contacts and/or pads may be fabricated for applying respective voltages to the saturable absorber 514 and the gain segments and/or sections 512. The ridge waveguide may be fabricated using various techniques, as appropriate for the application.

FIG. 7 provides a schematic cross-sectional diagram illustrating an example CPM laser 700 with the cross-section taken in a plane through the active region 711 of the optical cavity 710 of the CPM laser that is parallel to a surface 706 of a substrate 705 on which the CPM laser 700 is fabricated and/or disposed. In various embodiments, the active region 711 may be part of a ridge waveguide similar to ridge waveguide 120 that includes a waveguide structure in optical communication with the active region 711 via a surface of the waveguide structure and one or more layers of cladding (e.g., a first cladding disposed between substrate 705 and the active region 711 and a second cladding on a surface of a waveguide structure that is opposite the surface via which the waveguide structure is in optical communication with the active region 711).

The CPM laser 700 comprises an optical cavity 710 that is divided into two or more gain segments or sections 712 (e.g., 712A, 712B). In an example embodiment, adjacent gain segments or sections 712A, 712B are spatially separated from one another by a saturable absorber 714. For example, the saturable absorber 714 is disposed between the first gain segment or section 712A and the second gain segment and/or section 712B. In various embodiments, the gain segments or sections 712 comprise a gain or active material configured to generate light. For example, the gain segments or sections 712 may comprise an active material and/or semiconductor material comprising quantum wells configured to generate light.

The optical cavity 710 is defined by a first end 716A and a second end 716B. For example, the CPM laser 700 may emit light (e.g., in the form of frequency comb laser pulses) via the second end 716B. In an example embodiment at least one of the first end 716A or the second end 716B is defined by a grating 718 (e.g., 718A, 718B). For example, the grating 718 may be Bragg reflector including a plurality of alternating layers. The alternating layers include layers of a first material 722 (e.g., 722A, 722B, 722C) having a first mode effective refractive index interleaved between layers of a second material 724 (e.g., 724A, 724B) having a second mode effective refractive index. The first mode effective refractive index is different from and/or not equal to the second mode effective refractive index. In some embodiments, one of the first material or the second material is the gain material 709 of the active region 711 and the other of the first material or the second material is a different material. In some embodiments, neither the first material nor the second material is the gain material 709.

In various embodiments, the gratings 718 are configured to reflect light characterized by wavelengths within a selected wavelength range. The number of teeth in the grating determines the reflectivity, with more teeth resulting in higher reflectivity. In FIG. 7, the first grating 718A is illustrated as including five layers 722, 724. However, in various embodiments, the first grating 718A comprises a sufficient number of layers to be highly reflective for light characterized by wavelengths within an operational wavelength range of the CPM laser 700. For example, the first grating 718A may be configured to reflect more than 50% (e.g., more than 75%, more than 80%, more than 90%, more than 95%, more than 99%) of light characterized by wavelengths within the selected wavelength range and incident on the grating 718A from within the waveguide structure of the CPM laser 700 back into the waveguide structure.

In some embodiments, the first grating 718A and the second grating 718B may include the same number of layers 722, 724. In some embodiments, the second grating 718B may include fewer layers 722, 724 than the first grating 718A. For example, the second grating 718B is at least partially reflective for light characterized by wavelengths within the selected wavelength and configured to enable frequency comb laser pulses to be emitted through the second grating 718B.

The alternating layers of a first material 722 and the layers of a second material 724 of the gratings 718 are formed of materials with different refractive indices. A difference between the first mode effective refractive index (of the first material) and the second mode effective refractive index (or the second material) defines a width of the selected wavelength range. For example, the CPM laser 700 is configured to generate frequency comb laser pulses comprising teeth or spectral lines within the selected wavelength range.

In various embodiments the gratings 718A, 718B define respective ends 716A, 716B of the optical cavity 710. For example gain material 709 may extend beyond the gratings 718A, 718B. However, the gain material 709 that extends beyond the gratings is not part of the active region 711 of the optical cavity 710.

The ends 716A, 716B of the optical cavity are configured to provide gain segments or sections 712 of equal effective length. For example, the first gain segment or section 712A has a first effective length L₁ and the second gain segment or section 712B has a second effective length L₂. The first effective length L₁ is substantially equal to the second optical L₂ and/or a harmonic thereof. In some embodiments, the first effective length L₁ is substantially equal to the second optical L₂ (e.g., L₁=L₂).

In certain embodiments, the optical cavity may include three gain segments or sections (e.g., a left section, middle section, and right section). In such embodiments, the physical length of the left section and the right section may be half of the physical length of the middle section such that the double pass of a pulse in the left section and right section results in all three sections having equal optical lengths. As used herein, the effective lengths of the gain segments or sections are substantially equal to one another when the pulse travel time is consistent and/or uniform for each gain segment or section. For example, the pulse travel time in the first gain segment or section is the same as the pulse travel time in the second gain segment or section.

For example, as the gratings 718 may be defined using lithographic processes, the gain segments or sections 712 may be defined with very tight tolerances between the effective lengths of the gain segments or sections.

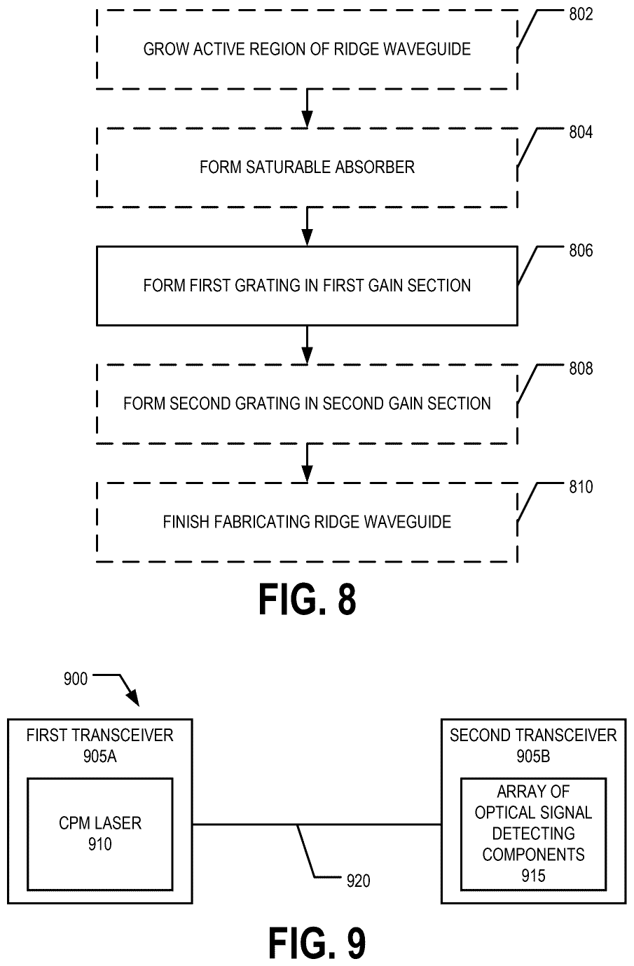

FIG. 8 provides a flowchart illustrating various processes and/or procedures for fabricating a CPM laser 700. Starting at block 802, a portion of a ridge waveguide is fabricated on a substrate 705. For example, a first cladding may be deposited on the substrate 705. The active gain material 709 of the active region 711 may be epitaxially grown on the first cladding.

At block 804, a saturable absorber 714 is formed to separate the first gain segment or section 712A and the second gain segment or section 712B. For example, the active material of the active region 711 may be trenched to electrically isolate the saturable absorber 714 from the first gain segment or section 712A and the second gain segment or section 712B.

At block 806, the first grating 718A is formed in the first gain segment or section 712A. For example, in certain embodiments, the first material is the gain material 709 and forming the first grating 718A comprises etching the gain material 709 to form layers of the first material 722 and slots and/or openings in the gain material 709. The etching may be performed using a lithographic etching process, in certain embodiments. The layers of the second material 724 may be formed by depositing the second material into the slots and/or openings in the gain material 709. The first grating 718A is finished, in some embodiments, with one or more clean up steps, chemical mechanical polishing, and/or the like.

At block 808, the second grating 718B is formed in the second gain segment or section 712B. For example, in certain embodiments, the first material is the gain material 709 and forming the second grating 718B comprises etching the gain material 709 to form layers of the first material 722 and slots and/or openings in the gain material 709. The etching may be performed using a lithographic etching process, in certain embodiments. The layers of the second material 724 may be formed by depositing the second material into the slots and/or openings in the gain material 709. The second grating 718B is finished, in some embodiments, with one or more clean up steps, chemical mechanical polishing, and/or the like.

In various embodiments, block 804 may be performed before performance of blocks 806 and 808. In certain embodiments, blocks 806 and 808 may be performed before performance of block 804. In some embodiments, blocks 804, 806, and 808 are performed at least partially overlapping in time. In some embodiments, blocks 806 and 808 are performed are at the same time and/or simultaneously. For example, the first grating 718A and the second grating 718B may be fabricated via the same lithographic etching and deposition processes and/or steps.

At block 810, a remainder of the ridge waveguide is fabricated. For example, a waveguide structure may be fabricated on the active region 711. For example, material of the waveguide structure may be deposited and/or grown on the active region 711. In some embodiments, a second cladding may be deposited on the waveguide structure. In various embodiments, one or more electrical contacts and/or pads may be deposited and/or patterned. For example, electrical contacts and/or pads may be fabricated for applying respective voltages to the saturable absorber 714, and the gain segments and/or sections 712. The ridge waveguide may be fabricated using various techniques, as appropriate for the application.

As a result of the accuracy of the placement of the first end 716A and/or the second end 716B (e.g., using a lithographic process to define the first grating 718A and/or the second grating 718B), the first effective length L₁ is equal to the second effective length L₂ with tighter tolerance compared to when the ends of the optical cavity are defined via traditional cleaving processes.

While examples herein may refer to quantum wells, the active material of the gain segments or sections 112, 162, 312, 512, 712 and saturable absorber 114, 164, 314, 514, 714 is not limited thereto. In certain embodiments, particularly those configured for high repetition rates (e.g., >100 GHz, 200 GHz), the active material comprises Quantum Dots (QD) or Quantum Dashes (QDash). In some such embodiments, the active material includes quantum wells in addition to QDs and/or QDashes. These active materials (e.g., active materials including QDs and/or QDashes) provide inhomogeneous broadening advantageous for wide spectral bandwidth frequency combs and offer higher gain saturation energies compared to traditional quantum wells.

### Example Optical Interconnect Including a CPM Laser

FIG. 9 illustrates an example optical interconnect 900 including one or more CPM lasers of various embodiments. As should be understood, CPM lasers of various embodiments may be incorporated into a variety of components, assemblies, and/or systems. Optical interconnects including one or more CPM lasers of various embodiments are illustrated herein to provide an example of on such component, assembly, and/or system in which CPM lasers of various embodiments may be incorporated.

The optical interconnect 900 comprises a first transceiver 905A and a second transceiver 905B. The first transceiver 905A is in optical communication with the second transceiver 905B via one or more optical fibers 920. The first transceiver 905A comprises one or more CPM lasers 910. In various embodiments, the one or more CPM lasers 910 are configured to generate frequency comb laser pulses. In an example embodiment, selected teeth or spectral lines of the frequency comb laser pulses may be used to perform coarse or dense WDM.

The second transceiver 905B comprises an array of optical signal detecting components 915. In various embodiments, the array of optical signal detecting components 915 is an array of photodiodes, photodetectors, and/or other optical signal detecting devices.

For example, the first transceiver 905A comprises one or more CPM lasers configured to generate frequency comb laser pulses. A CPM laser 910 generates a frequency comb laser pulse and one or more teeth or spectral lines of the frequency comb laser pulse are modulated to provide an optical signal having, possibly, multiple channels of data encoded therein. The optical signal is then provided to the second transceiver 905B via the optical fiber 920, for example. One or more optical signal detecting components that may include respective photodiodes and/or other photodetectors may receive and/or detect respective portions of the optical signal (e.g., corresponding to respective teeth of spectral lines of the frequency comb laser pulse) such that information is communicated from the first transceiver 905A to the second transceiver 905B via the optical signal(s).

### Example Datacenter

In various embodiments, a system includes a CPM laser configured to generate and provide frequency comb laser pulses. For example, the CPM laser may be used as a coarse or dense WDM optical source. For example, as shown in FIG. 8, CPM laser of various embodiments may be incorporated into an optical interconnect. Such an optical interconnect may be part of a datacenter.

For example, an optical interconnect comprising one or more CPM lasers of various embodiments may be used to place various components of a datacenter in communication with one another. In various embodiments, the system may include a pluggable optical interconnect, a chip-to-chip optical interconnect, an optical network comprising a plurality of optical interconnect, dense Wavelength Division Multiplexing (WDM) optical links, WDM or DWDM source and/or the like that includes one or more CPM lasers of various embodiments. For example, a CPM laser may be configured to generate optical signals and may be used to generate optical signals that are transmitted along one or more optical communication paths between two components of a datacenter, in accordance with an example embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

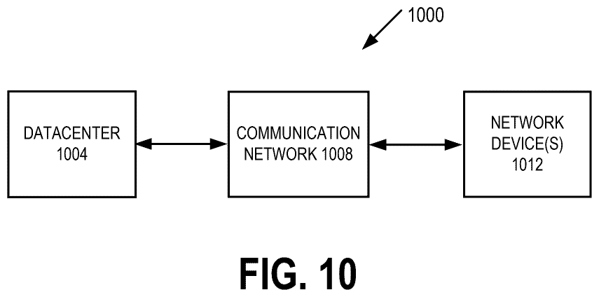

FIG. 10 illustrates a system 1000 according to at least one example embodiment. The system 1000 includes a datacenter 1004, a communication network 1008, and one or more network devices 1012. In at least one example embodiment, the datacenter 1004 corresponds to a collection of network devices, such as network switches (e.g., Ethernet switches) connected with a collection of servers or compute nodes. The datacenter 1004 may adhere to a networking topology (e.g., a hierarchal networking topology), such as a fat tree topology, a Slim Fly topology, a Dragonfly topology, and/or the like. The datacenter 1004 routes traffic amongst the network switches and servers therein, and at least one layer of the topology in the datacenter 1004 is coupled to the communication network 1008 to allow networking traffic to flow between the datacenter 1004 and the network device(s) 1012.

Examples of the communication network 1008 that may be used to connect the datacenter 1004 and the network device(s) 1012 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 1012 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 1008. In at least one example embodiment, the one or more network devices 1012 correspond to another datacenter, similar to or the same as datacenter 1004.

As noted above, the datacenter 1004 and/or the network device(s) 1012 may include storage devices and/or processing circuitry for carrying out computing tasks, for example, tasks associated with controlling the flow of data internally and/or over the communication network 1008. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 1004 and network device(s) 1012 may include one or more communication interfaces for facilitating wired and/or wireless communication between one another and other unillustrated elements of the system 1000.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

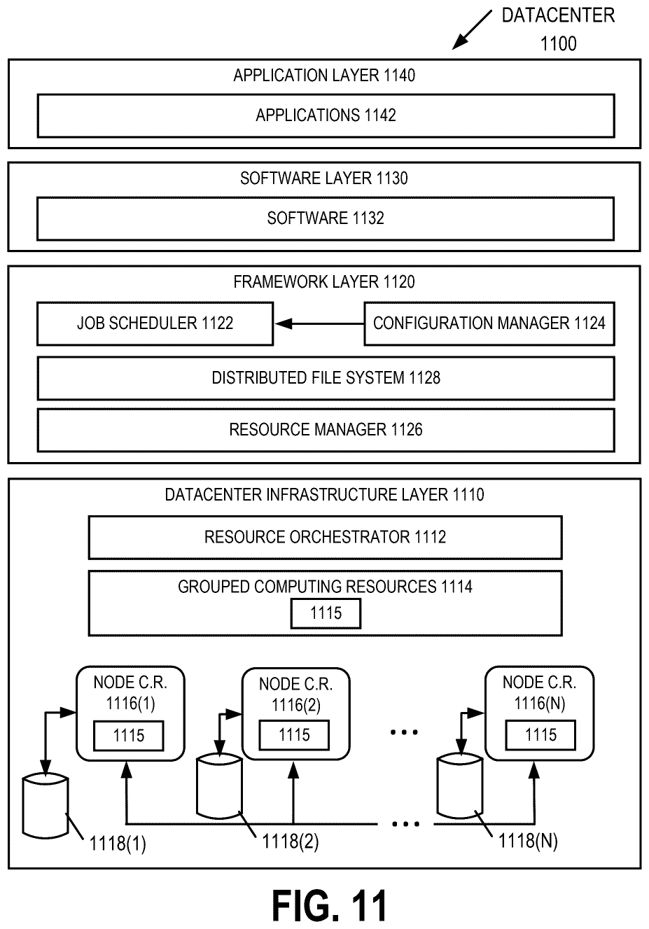

FIG. 11 illustrates an example datacenter 1100, in which at least one embodiment may be used. In at least one embodiment, datacenter 1100 includes a datacenter infrastructure layer 1110, a framework layer 1120, a software layer 1130, and an application layer 1140.

In at least one embodiment, as shown in FIG. 11, datacenter infrastructure layer 1110 may include a resource orchestrator 1112, grouped computing resources 1114, and node computing resources (“node C.R.s”) 1116(1)-1116(N), where “N” represents a positive integer (which may be a different integer “N” than used in other figures). In at least one embodiment, node C.R.s 1116(1)-1116(N) may include, but are not limited to, any number of central processing units (“CPUs”) or other processors (including accelerators, field programmable gate arrays (FPGAs), graphics processors, etc.), memory storage devices 1118(1)-1118(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 1116(1)-1116(N) may be a server having one or more of above-mentioned computing resources.

In at least one embodiment, grouped computing resources 1114 may include separate groupings of node C.R.s housed within one or more racks (not shown), or many racks housed in datacenters at various geographical locations (also not shown). In at least one embodiment, separate groupings of node C.R.s within grouped computing resources 1114 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1112 may configure or otherwise control one or more node C.R.s 1116(1)-1116(N) and/or grouped computing resources 1114. In at least one embodiment, resource orchestrator 1112 may include a software design infrastructure (“SDI”) management entity for datacenter 1100. In at least one embodiment, resource orchestrator 1112 may include hardware, software or some combination thereof.

In at least one embodiment, as shown in FIG. 11, framework layer 1120 includes a job scheduler 1122, a configuration manager 1124, a resource manager 1126 and a distributed file system 1128. In at least one embodiment, framework layer 1120 may include a framework to support software 1132 of software layer 1130 and/or one or more application(s) 1142 of application layer 1140. In at least one embodiment, software 1132 or application(s) 1142 may respectively include web-based service software or applications, such as those provided by Amazon Web Services, Google Cloud and Microsoft Azure. In at least one embodiment, framework layer 1120 may be, but is not limited to, a type of free and open-source software web application framework such as Apache Spark™ (hereinafter “Spark”) that may utilize distributed file system 1128 for large-scale data processing (e.g., “big data”). In at least one embodiment, job scheduler 1122 may include a Spark driver to facilitate scheduling of workloads supported by various layers of datacenter 1100. In at least one embodiment, configuration manager 1124 may be capable of configuring different layers such as software layer 1130 and framework layer 1120 including Spark and distributed file system 1128 for supporting large-scale data processing. In at least one embodiment, resource manager 1126 may be capable of managing clustered or grouped computing resources mapped to or allocated for support of distributed file system 1128 and job scheduler 1122. In at least one embodiment, clustered or grouped computing resources may include grouped computing resources 1114 at datacenter infrastructure layer 1110. In at least one embodiment, resource manager 1126 may coordinate with resource orchestrator 1112 to manage these mapped or allocated computing resources.

In at least one embodiment, software 1132 included in software layer 1130 may include software used by at least portions of node C.R.s 1116(1)-1116(N), grouped computing resources 1114, and/or distributed file system 1128 of framework layer 1120. In at least one embodiment, one or more types of software may include, but are not limited to, Internet web page search software, e-mail virus scan software, database software, and streaming video content software.

In at least one embodiment, application(s) 1142 included in application layer 1140 may include one or more types of applications used by at least portions of node C.R.s 1116(1)-1116(N), grouped computing resources 1114, and/or distributed file system 1128 of framework layer 1120. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1124, resource manager 1126, and resource orchestrator 1112 may implement any number and type of self-modifying actions based on any amount and type of data acquired in any technically feasible fashion. In at least one embodiment, self-modifying actions may relieve a datacenter operator of datacenter 1100 from making possibly bad configuration decisions and possibly avoiding underutilized and/or poor performing portions of a datacenter.

In at least one embodiment, datacenter 1100 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 1100. In at least one embodiment, trained machine learning models corresponding to one or more neural networks may be used to infer or predict information using resources described above with respect to datacenter 1100 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1115 are used to perform inferencing and/or training operations associated with one or more embodiments. In at least one embodiment, inference, and/or training logic 1115 may be used in system FIG. 11 for inferencing or predicting operations based, at least in part, on weight parameters calculated using neural network training operations, neural network functions and/or architectures, or neural network use cases described herein.

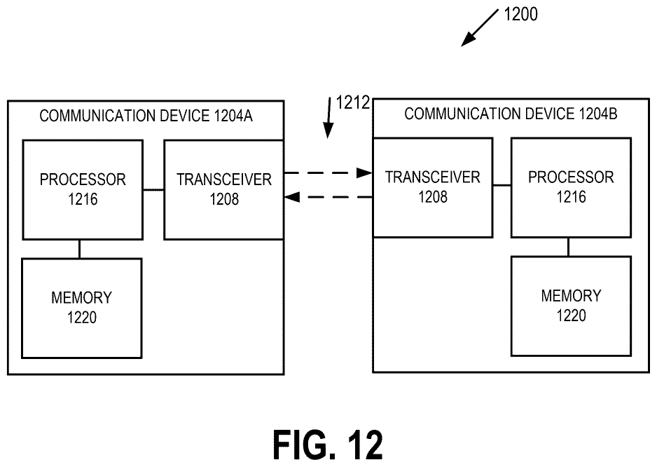

FIG. 12 illustrates a system 1200 including a first communication device 1204A and a second communication device 1204B. Illustratively, but without limitation, the communication devices 1204 (e.g., 1204A, 1204B) may correspond to network devices (e.g., network devices 1012). As such, the communication devices 1204 may correspond to any type of device that becomes part of or is connected with a communication network (e.g., communication network 1008). Examples of suitable devices that may act or operate like a communication device 1204 as described herein include, without limitation, one or more of a Personal Computer (PC), a laptop, a tablet, a smartphone, a server, a collection of servers, a networking card, an edge router, a switch, Network Interface Controller, a Top of Rack (ToR) switch, a server blade, or the like. The communication device 1204 may include a transceiver 1208, a processor 1216, and memory 1220. The transceiver 1208 may include hardware that enables communications over the communication channel 1212 whereas the processor 1216 and memory 1220 may include components that enable the communication device 1204 to provide a desired functionality or perform certain functions.

The communication channel 1212 may traverse a datacenter or any type of communication network (whether trusted or untrusted). Examples of a communication network that may be used to connect communication devices 1204 and support the communication channel 1212 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 1204 using optical signals. In this case, the communication devices 1204 and the communication network may include waveguides (e.g., optical fibers) that carry the optical signals. For example, the communication devices and/or the communication network may include one or more CPM lasers 100, 300, 500, 700, according to various embodiments.

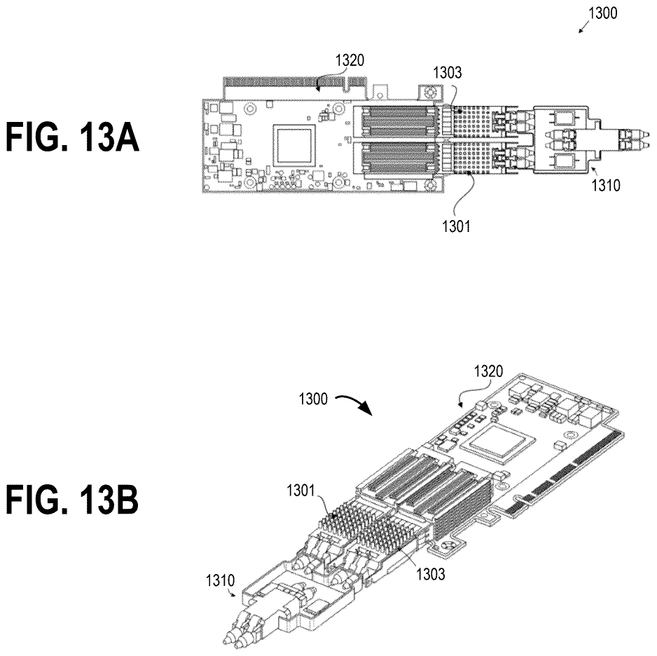

FIGS. 13A and 13B illustrate a top view and a perspective view, respectively, of a transceiver module operatively coupled to a network adapter, in the present example a Network Interface Controller (NIC) 1300, in accordance with an embodiment of the disclosure. As shown in FIGS. 13A and 13B, the transceiver module may include a first optical module 1301, a second optical module 1303, an adapter 1310, and a dual-port NIC 1320 of a server. Both the first optical module 1301 and the second optical module 1303 may be dual-fiber transceivers that are configured for duplex communication that allows the source (e.g., server) to communicate with the target (e.g., leaf switch) in both directions. The adapter 1310 may be a ganged physical component configured to link the first optical module 1301 and the second optical module 1303 for the purpose of transmitting and receiving data to and from the leaf switch.

In some embodiments, the adapter 1310 may be configured to operate in two configurations, such as a first configuration and a second configuration. In one aspect, the first configuration may be a default configuration of operation, where the first optical module 1301 may be operationally active. The second configuration may be a contingent configuration that is implemented when the first optical module 1301 operationally fails. When such a failure is detected, the second optical module 1303, which is otherwise operationally inactive or idle, may be engaged to become operationally active and handle all network traffic that was initially handled by the first optical module 1301.

In some embodiments, the transceiver module 1300 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 1300 may be configured to operate between the server and the leaf layer. In particular, as shown in FIGS. 13A and 13B, the adapter 1310 may be operatively coupled to the first optical module 1301 and the second optical module 1303, while the first optical module 1301 and the second optical module 1303 may be operatively coupled to a dual-port NIC 1320 of a server.

In embodiments, NIC 1300 may comprise one or more processing circuits, as detailed above; the processing circuits may comprise FW, that is loaded according to the techniques described above.

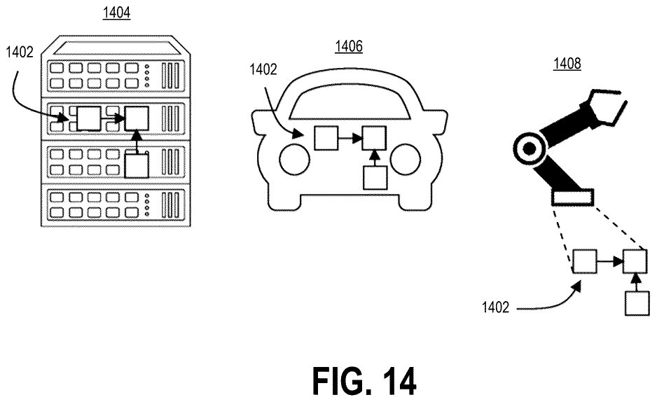

FIG. 14 depicts some exemplary scenarios for use of an optical transceiver 1402 in accordance with some embodiments. An optical transceiver 1402 may be utilized in a computing system 1404 (e.g., in a server farm, or within a server computer system), a vehicle 1406 (e.g., a car, truck, train, or airplane), and a robot 1408 (or among robots in a factory), to name just a few examples. The optical transceiver 1402 may be particularly useful for high-speed communication in environments subject to high levels of electromagnetic interference (EMI).

### Example System Use Case

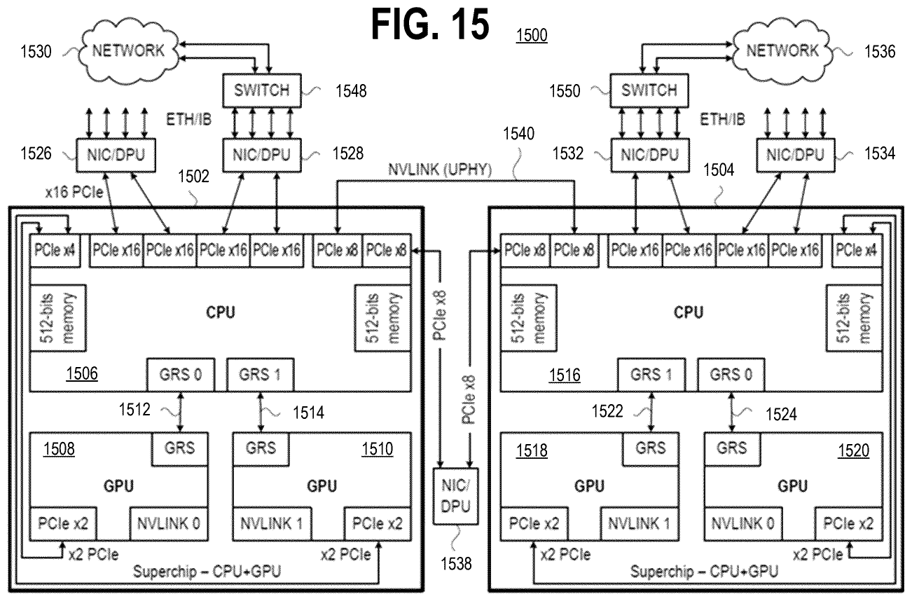

FIG. 15 is a block diagram that schematically illustrates a computing system 1500, e.g., a data center or a High-Performance Computing (HPC) cluster, in accordance with an embodiment that is described herein. System 1500 comprises a plurality of subsystems, e.g., multiple processing devices coupled to each other, multiple network devices, and multiple networks, according to at least one embodiment. Computing system 1500 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1500 and to one or more external networks 1530, 1536. In the present example, system 1500 comprises a packet switch 1548 that connects NIC/DPU 1528 to network 1530, and a packet switch 1550 that connects NIC/DPU 1532 to network 1536.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1500 can include one or more CPUs and one or more GPUs.

FIG. 15 also demonstrates an example architecture of a multi-GPU architecture. As illustrated in the figure, computing system 1500 includes a processing device 1502 with a multi-GPU architecture. In particular, processing device 1502 may be a system-on-chip and includes multiple subsystems such as a CPU 1506, a GPU 1508, and a GPU 1510. CPU 1506 can be coupled to GPU 1508 via a die-to-die (D2D) or chip-to-chip (C2C) interconnect 1512, such as a Ground-Referenced Signaling interconnect (GRS interconnect). CPU 1506 can be coupled to GPU 1510 via a D2D or C2C interconnect 1514. CPU 1506 can also couple to GPU 1508 and GPU 1510 via PCIe interconnects.

CPU 1506 can be coupled to one or more NICs or DPUs, which are coupled to one or more networks. For example, as illustrated in FIG. 3, CPU 1506 is coupled to a first NIC/DPU 1526, which is coupled to a network 1530. CPU 1506 is also coupled to a second NIC/DPU 1528, which is coupled to network 1530 via switch 1548. NIC/DPU 1526 and NIC/DPU 1528 can be coupled to network 1530 over Ethernet (ETH), NVLINK or InfiniBand (IB) connections, for example.

Computing system 1500 also includes a processing device 1504 with a multi-GPU architecture. In particular, processing device 1504 includes multiple subsystems including a CPU 1516, a GPU 1518, and a GPU 1520. CPU 1516 can be coupled to GPU 1518 via an D2D or C2C interconnect 1522. CPU 1516 can be coupled to GPU 1520 via a D2D or C2C interconnect 1524. CPU 1516 can also couple to GPU 1518 and GPU 1520 via PCIe interconnects. CPU 1516 can be coupled to one or more NICs or DPUs, which are coupled to one or more networks. For example, as illustrated in FIG. 3, CPU 1516 is coupled to a first NIC/DPU 1532, which is coupled to a network 1536. CPU 1516 is also coupled to a second NIC/DPU 1534, which is coupled to network 1536 via switch 1550. NIC/DPU 1532 and NIC/DPU 1534 can be coupled to network 1536 over Ethernet (ETH), NVLINK or InfiniBand (IB) connections.

In at least one embodiment, processing device 1502 and processing device 1504 can communicate with each other via a NIC/DPU 1538, such as over PCIe interconnects. Processing device 1502 and processing device 1504 can also communicate with each other over a high-bandwidth communication interconnects 1540, such as an NVLink interconnect or other high-speed interconnects. The packet switches in FIG. 3 may comprise, for example, Nvidia Quantum-2 switches. The NICs/DPUs in the figure may comprise, for example, Nvidia Bluefield DPUs.

In various embodiments, one or more of the interconnects 1512, 1514, 1522, 1524 may be optical interconnects disclosed herein. Additionally, in various embodiments, switches 1548, 1550 may be in communication with NIC/DPU 1528, 1532, respectively, via one or more optical interconnects disclosed herein. In some embodiments, NIC/DPU 1526, 1534 may be in communication with one or more additional elements via optical interconnects disclosed herein. For example, various elements of the computing system 1500 may be in communication with one another via one or more optical interconnects disclosed herein.

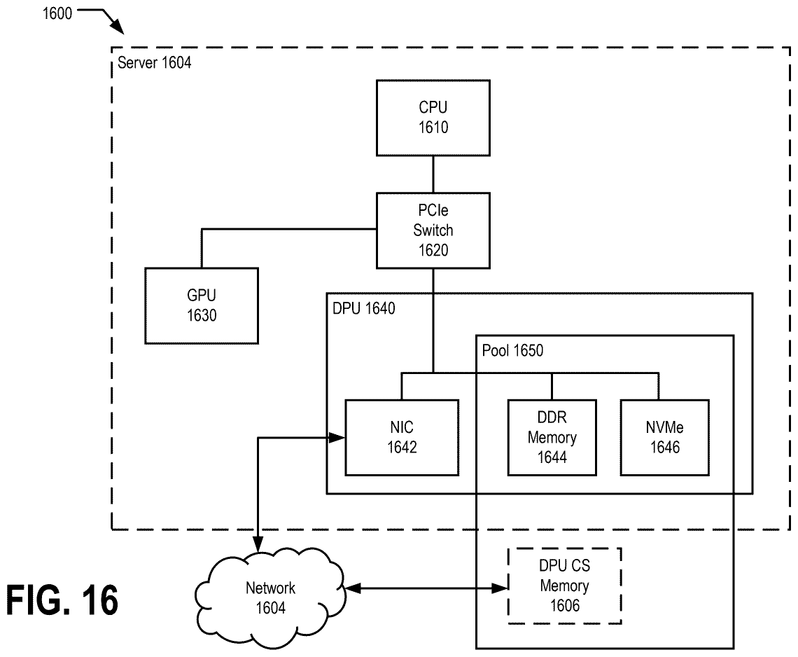

FIG. 16 illustrates an example computing environment 1600 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1600 may include a server 1602 which may be used to perform high performance computing (HPC) workloads, such as AI training or machine learning model training. In an embodiment, the server 1602 may be an application instance or a compute node. The server 1602 may include a CPU 1610 associated with a switch 1620, such as a peripheral component interconnect express (PCIe) switch, which may control at least some data transmission over communication paths interconnecting various components. In an embodiment, the CPU 1610 may include a root complex processor.

The PCIe switch 1620 may also be associated with a GPU 1630 and a DPU 1640, and may transmit data between at least some of the CPU 1610, the GPU 1630, the DPU 1640, and other components (e.g., via one or more optical interconnects disclosed herein). In an embodiment, the PCIe switch 1620 may be associated with more than one GPU or more than one DPU. In another embodiment, the PCIe switch 1620 may be located within the DPU 1640. The PCIe switch 1620 may manage the transfer of at least some data between the CPU 1610, the GPU 1630, and the DPU 1640. In another embodiment, the number of GPUs associated with the PCIe switch 1620 may be equal to the number of DPUs associated with the PCIe switch 1620. In at least one embodiment, the server 1602 may include, without limitation, any number of the CPUs 1610, the PCIe switches 1620, the GPUs 1630, and/or the DPUs 1640, in any combination. For example, in at least one embodiment, server 1602 could include eight, sixteen, thirty-two, and/or more GPUs 1630. In at least one embodiment, communication paths interconnecting various components, including but not limited to the CPU 1610, the PCIe switch 1620, the GPU 1630, and the DPU 1640, in FIG. 16 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1640 may include a network interface controller (NIC) 1642, a DDR memory 1644, and a non-volatile memory express (NVMe) device 1646. The NIC 1642 may be able to interface with a network 1604, which may also interface with additional NVMe devices available to the DPU 1640, such as over fabric. In an embodiment, the DPU 1640 may not include the NVMe device 1646. In another embodiment, the NVMe device 1646 may be located on the server 1602 and not on the DPU 1640. In yet another embodiment, the computing environment 1600 may include more than one of the NVMe device 1646, such as a first NVMe device in the DPU 1640 and a second NVMe device on the server 1602 and associated directly with the PCIe switch 1620. In an embodiment, the DPU 1640 may not include the DDR memory 1644 and may include a computational storage services (CSS) in place of, or in addition to, the DDR memory 1644. For example, computing environment 1600 may include DPU computational storage (CS) memory 1606 available to the DPU 1640 as part of the CSS. The network 1604 may be able to interface with the DPU CS memory 1606 through the NIC 1642, according to any suitable interface protocol, such as remote direct memory access (RDMA) over Ethernet, InfiniBand, Fiber Channel, etc.

The total memory of the computing environment 1600 available for data storage may be expanded through the use of the DPU 1640 on nodes of the system. The DPU 1640 may have access to a pool 1650 of memory already available to the server 1602, such as double data rate (DDR) memory, on-board NVMe devices, NVMe devices over fabric, and CS. The pool 1650 of memory may include at least one of the DDR memory 1644, NVMe 1646, and the DPU CS memory 1606. The DPU 1640 may also be able to access the available memory of other DPUs as part of the pool 1650, and other DPUs may be able to access the available memory of DPU 1640, such as the pool 1650. This available memory can be accessed and utilized for data storage, without the addition of compute resources, such as compute nodes, which would be required using other solutions. The available pool 1650 accessible to the DPU 1640 may be provisioned for the server 1602 to expand the total memory available for data storage, such as to reduce the data storage load on the CPU 1610 or the GPU 1630, which can instead increase the utilization of their memory for processing. For example, during training of an AI, the model states, residual states, activation functions, and checkpoints can be stored, or offloaded, on the pool 1650 accessible to the DPU 1640.

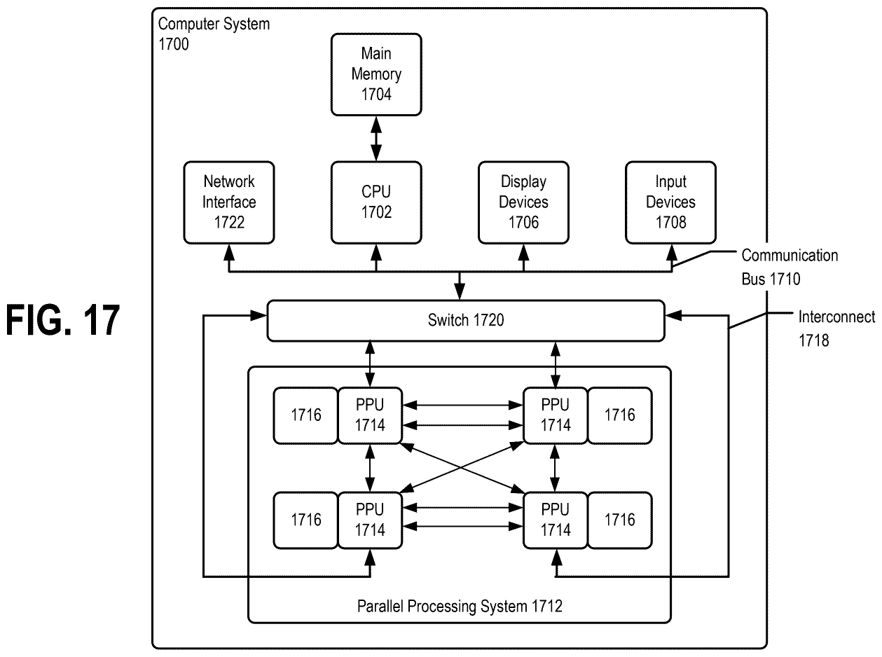

FIG. 17 illustrates a computer system 1700, according to at least one embodiment. In at least one embodiment, computer system 1700 comprises at least one optical interconnect of an example embodiment.

In at least one embodiment, computer system 1700 comprises, without limitation, at least one central processing unit (“CPU”) 1702 that is connected to a communication bus 1710 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1700 includes, without limitation, a main memory 1704 and control logic (e.g., implemented as hardware, software, or a combination thereof) and data are stored in main memory 1704 which may take form of random access memory (“RAM”). In at least one embodiment, a network interface subsystem (“network interface”) 1722 provides an interface to other computing devices and networks for receiving data from and transmitting data to other systems from computer system 1700.

In at least one embodiment, computer system 1700, in at least one embodiment, includes, without limitation, input devices 1708, parallel processing system 1712, and display devices 1706 which can be implemented using a conventional cathode ray tube (“CRT”), liquid crystal display (“LCD”), light emitting diode (“LED”), plasma display, or other suitable display technologies. In at least one embodiment, user input is received from input devices 1708 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1704 and/or secondary storage. Computer programs, if executed by one or more processors, enable system 1700 to perform various functions in accordance with at least one embodiment, memory 1704, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1702; parallel processing system 1712; an integrated circuit capable of at least a portion of capabilities of both CPU 1702; parallel processing system 1712; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1700 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1712 includes, without limitation, a plurality of parallel processing units (“PPUs”) 1714 and associated memories 1716. In at least one embodiment, PPUs 1714 are connected to a host processor or other peripheral devices via an interconnect 1718 and a switch 1720 or multiplexer. In at least one embodiment, parallel processing system 1712 distributes computational tasks across PPUs 1714 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1714, although such shared memory may incur performance penalties relative to use of local memory and registers resident to a PPU 1714. In at least one embodiment, operation of PPUs 1714 is synchronized through use of a command such as_syncthreads( ), wherein all threads in a block (e.g., executed across multiple PPUs 1714) to reach a certain point of execution of code before proceeding.

The PPUs 1714 may be in communication with one another and/or switch 1720 via one or more optical interconnects in accordance with example embodiments disclosed herein.

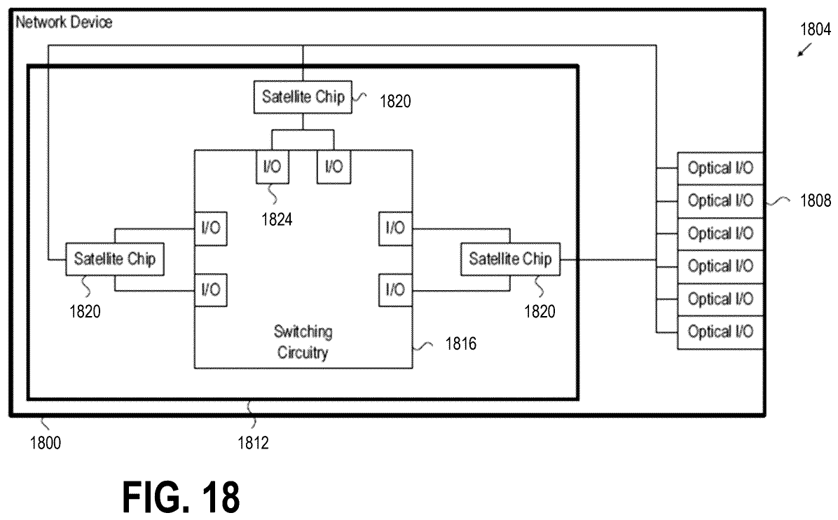

Co-packaging may refer to the close integration of different electrical and/or optoelectronic chips in the same package. FIG. 18 is a block diagram that schematically illustrates a co-packaged Networking Device 1800, in accordance with an embodiment that is disclosed herein. The different chips that constitute a co-packaged Networking Device are assembled on a single substrate in what is typically called the MCM assembly 1812. The MCM assembly 1812 can include a switching circuitry 1816 surrounded by peripheral or satellite chips 1820. In some embodiments, the switching circuitry 1816 and surrounding satellite chips 1820 are all mounted on a common substrate, although such a configuration is not required. The MCM assembly 1812 may be provided in a larger housing of the networking device 1812, positioned behind the front panel 1804. The switching circuitry 1816 may include one or more core digital Application Specific Integrated Circuits (ASICs), CPUs, GPUs, microprocessors, FPGAs, combinations thereof, and the like. The switching circuitry 1816 may include a number of input ports and/or output ports 1828. The Input/Output (I/O) ports 1824 may include electrical ports and/or optical ports. Additionally, the switching circuitry 1816 may include a combination of electrical blocks and optical blocks. The electrical blocks of the switching circuitry 1816 may include a number of electrical switches that are configured to route signals in an electrical domain. The optical blocks of the switching circuitry 1816 may include a number of optical components that are configured to generate, detect, and route signals in an optical domain. The MCM assembly 1812, in some embodiments, may concern or include multiple satellite chips 1820 that are assembled on the same substrate as the switching circuitry 1816. In some embodiments, a configuration of the optical block(s) and a configuration of the electrical block(s) depends (e.g., is based on) on the number of optical ports in the I/O ports 1824.

As discussed above, optical I/Os 1808, which may also be referred to as optical connectors, are placed at the front panel 1804. As mentioned above, connectivity between the MCM assembly 1812 and optical I/Os 1808 may be transferred to the front panel 1804 through optical fibers. This connection may be made directly with an optical I/O 1824 of the switching circuitry or may be made with one or more of the satellite chips 1820. The connection is often made with one or more of the satellite chips 1820 because the satellite chips 1820 may include the electro-optic converters and, possibly, the serializer/deserializer (SERDES) to natively support the connection. The satellite chips 1820 may include one or more of aDSP processor, driver, trans-impedance amplifier, laser, modulator, photodiode, serializer-deserializer, or the like.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

### Conclusion

Many modifications and other embodiments will come to mind to one skilled in the art to which this disclosure pertains to having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method comprising:
fabricating a colliding pulse mode-locked (CPM) laser having a first gain section and a second gain section, the first gain section and the second gain section having respective effective lengths that are substantially equal such that co-propagating pulses generated within the first gain section and the section gain section, respectively, collide at a boundary between the first gain section and the second gain section to cause harmonic generation.

2. The method of claim 1, wherein fabricating the CPM laser comprises etching at least a portion of the first gain section to define an effective length of the first gain section, wherein the first gain section is one of at least two gain sections of a cavity of the CPM laser.

3. The method of claim 1, wherein the boundary between the first gain section and the second gain section is a saturable absorber and the effective length of the first gain section is defined to be substantially equal to an effective length of the second gain section.

4. The method of claim 1, wherein the CPM laser further comprises a third gain section with the second gain section positioned between the first gain section and the third gain section and an effective length of at least one of the first gain section or the third gain section is determined based at least in part on a cleaving distance of a cleaving process to be used to define an end of the at least one of the first gain section or the third gain section.

5. The method of claim 4, wherein the second gain section has a middle section effective length and a side gain section effective length of the at least one of the first gain section or the third gain section is determined based on the middle section effective length and an effective length corresponding to the cleaving distance.

6. The method of claim 5, wherein fabricating the CPM laser comprises performing the cleaving process to define the end of the at least one of the first gain section or the third gain section.

7. The method of claim 1, further comprising forming a saturable absorber, wherein forming the saturable absorber comprises electrically isolating the saturable absorber from the first gain section and the second gain section and defining electrodes configured for injecting current into the saturable absorber, wherein the saturable absorber is the boundary that separates the first gain section from the second gain section.

8. The method of claim 1, wherein fabricating the CPM laser comprises:
forming a C-shaped optical cavity comprising the first gain section and the second gain section and the boundary between the first gain section and the second gain section is a saturable absorber located at a center of a curve of the C-shaped optical cavity; and
cleaving both the first gain section and the second gain section in a same cleaving process.

9. The method of claim 8, further comprising, prior to cleaving the first gain section and the second gain section, etching partially through respective ends of the first gain section and the second gain section to define respective cantilevered portions at the ends of the first gain section and the second gain section and the cleaving is configured to cleave off the cantilevered portions.

10. The method of claim 8, wherein the first gain section and the second gain section have the same effective length.

11. The method of claim 1, wherein fabricating the CPM) laser comprises:
forming a first grating in the first gain section of an optical cavity comprising the first gain section and the second gain section, the first grating defining an effective length of the first gain section and configured to substantially reflect light characterized by wavelengths within a selected wavelength range.

12. The method of claim 11, wherein the first grating is formed using at least one lithographic process.

13. The method of claim 11, further comprising forming a second grating in the second gain section of the optical cavity, the second grating defining an effective length of the second gain section and configured to substantially reflect light characterized by wavelengths within the selected wavelength range.

14. The method of claim 11, wherein the first grating comprises alternating layers of a first material having a first mode effective refractive index and a second material having a second mode effective refractive index, the first mode effective refractive index is not equal to the second mode effective refractive index, and a difference between the first mode effective refractive index and the second mode effective refractive index defines a width of the selected wavelength range.

15. A colliding pulse mode-locked (CPM) laser comprising:
an optical cavity comprising at least two gain sections, wherein a saturable absorber is disposed between adjacent gain sections of the at least two gain sections and wherein a first gain section of the at least two gain sections and a second gain section of the at least two gain sections have respective effective lengths that are substantially equal.

16. The CPM laser of claim 15, wherein the optical cavity is a C-shaped optical cavity and the saturable absorber is disposed at a center of a curve of the C-shaped optical cavity.

17. The CPM laser of claim 15, wherein at least one gain section of the at least two gain sections is defined at least in part by cleaved end.

18. The CPM laser of claim 17, wherein an effective length of the gain section that is defined at least in part a cleaved end is configured such that an effective length of the gain section that is defined at least in part by the cleaved end corresponds to a cleaving distance of a cleaving process used to form the cleaved end.

19. The CPM laser of claim 15, wherein the active material of the at least two gain sections comprises at least one layer of Quantum Dots (QD) or Quantum Dashes (QDash).

20. The CPM laser of claim 15, wherein the CPM laser is configured to operate with a repetition rate of at least 100 GHz.
